(19) United States
(12) Patent Application Publication
(10) Pub. No.: US 2011/0097518 A1
(43) Pub. Date: Apr. 28, 2011

(54) VERTICALLY INTEGRATED PROCESSING CHAMBER

(75) Inventor: Donald J.K. Olgado, Palo Alto, CA (US)

(73) Assignee: APPLIED MATERIALS, INC., Santa Clara, CA (US)

(21) Appl. No.: 12/914,996

(22) Filed: Oct. 28, 2010

Related U.S. Application Data
(60) Provisional application No. 61/255,703, filed on Oct. 28, 2009.
(60) Provisional application No. 61/255,731, filed on Oct. 28, 2009.

(51) Int. Cl. H05H 1/46; C23C 16/453

(52) U.S. Cl. 427/575; 118/719; 427/569

(57) ABSTRACT

A method and apparatus for plasma processing of substrates in a substantially vertical orientation is described. Substrates are positioned on a carrier comprising at least two frames oriented substantially vertically. The carrier is disposed in a plasma chamber with an antenna structure positioned between the substrates. Multiple plasma chambers may be coupled to a transfer chamber with a turntable for directing the carrier to a target chamber. A loader moves substrates between the carrier and a load-lock chamber in which substrates are staged in a substantially horizontal position.

### CROSS-REFERENCE TO RELATED APPLICATIONS

This application claims benefit of U.S. provisional patent application Ser. No. 61/255,703, filed Oct. 28, 2009, and U.S. Provisional Patent Application Ser. No. 61/255,731, which are both herein incorporated by reference.

### FIELD

Embodiments described herein relate to apparatus and methods for processing semiconductor substrates. More specifically, apparatus and methods for integrated processing of semiconductor substrates in a substantially vertical position are described.

### BACKGROUND

Large substrates are commonly processed in manufacturing many semiconductor articles. The most common end use applications for large semiconductor substrates are photovoltaic panels and large display substrates. These substrates are subjected to a number of processing steps in a typical process, including material deposition steps, material removal steps, cleaning steps, and the like. In most such processes, the substrates are treated and transported in a substantially horizontal position, and are frequently processed one at a time.

Processing large substrates in a horizontal position increasing requires large footprint equipment to achieve desired throughput. Such equipment is expensive to construct and operate, driving up the unit cost of each substrate. In addition, processing of substrates one at a time also drives up cost.

As the market for large semiconductor substrates grows, there remains a need for large substrate manufacturing processes that are cost effective to build and operate.

### SUMMARY

Methods and apparatus for processing substrates in a substantially vertical position are described. The substrates are mounted on a carrier, which moves the substrates to a substantially vertical processing chamber. The substrates move on the carrier from one chamber to another in a system for processing substrates in a substantially vertical orientation.

A chamber for plasma processing of substrate, the chamber having an enclosure with a substantially vertical major axis, is described. An antenna structure is centrally located within the enclosure, oriented parallel to the substantially vertical major axis, and coupled to a power source. Two substrate processing regions are defined within the enclosure. The substrate processing regions share a common volume and are separated by the antenna structure.

In another embodiment, a process of treating substrates is also described that involves simultaneously plasma processing two substrates in a substantially vertical orientation within a vertical plasma processing chamber. A single plasma field is generated in the substantially vertical plasma processing chamber, and the two substrates are simultaneously processed using the single plasma field.

In yet another embodiment, a system is described for vacuum processing of substrates in a substantially vertical orientation. The system includes a substantially vertical plasma processing chamber coupled to a load-lock chamber, a carrier for transporting substrates in a substantially vertical orientation within the system, and a loader for moving substrates between the load-lock chamber and the carrier.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of certain embodiments of a multijunction solar cell oriented toward the light or solar radiation.

FIG. 2 is a schematic diagram of the multi-junction solar cell of FIG. 1 further comprising an n-type amorphous silicon buffer layer.

FIG. 3 is a schematic diagram of the multi-junction solar cell of FIG. 1 further comprising a p-type microcrystalline silicon contact layer.

FIGS. 4A-4B are cutout views different embodiments of a process chamber with a centrally located antenna structure.

FIG. 5 is a cutout view of another embodiment of a process chamber with a centrally located antenna structure.

FIG. 6 is a three dimensional view of a process system having vertical processing chambers.

FIG. 7 is a top schematic view of one embodiment of a process system having a plurality of vertical substrate process chambers.

FIG. 8 is a top schematic view of another embodiment of a process system having a plurality of vertical substrate process chambers.

FIG. 9 is a three dimensional view of a process system having vertical processing chambers.

FIG. 10A is an embodiment of a load lock chamber, and substrate re-orient and framing chamber with one vacuum robot.

FIG. 10B is another embodiment of a load lock chamber, and a substrate re-orient and framing chamber with two vacuum robots.

FIG. 11A is an embodiment of a robot holding a substrate.

FIG. 11B is an embodiment of a robot holding a substrate that has been rotated from a horizontal position to a vertical position.

FIG. 11C is an embodiment of a robot mounting a substrate onto a frame.

FIG. 12A is an embodiment of two single substrate frames.

FIG. 12B is an embodiment of a dual substrate frame positioned on rollers.

FIG. 12C is an embodiment of a dual substrate frame moving through the process system of FIG. 9.

FIG. 13A is a schematic cross-section view of one embodiment of a dual substrate frame.

FIG. 13B is a schematic cross-section view of another embodiment of a dual substrate frame.

FIG. 13C is a schematic cross-section view of a third embodiment of a dual substrate frame.

FIG. 13D is a schematic cross-section view of two electrostatic chucks with fingers forming a dual substrate frame.

FIG. 13E is a schematic cross-sectional view of a process chamber with a dual substrate frame sitting in the process chamber.

FIG. 13F is schematic cross-sectional view of a process chamber with another embodiment of a dual substrate frame.

FIGS. 13G and H are schematic cross-section views of other embodiments of a dual substrate frames.

FIG. 13I is schematic cross-sectional view of a process chamber with another embodiment of a dual substrate frame.

FIG. 13J is a top view of the process chamber of FIG. 13I.

FIG. 14 is a three dimensional view of the process system of FIG. 9 with a frame transport car.

FIG. 15 is another cross sectional view of the process system of FIG. 9 with a frame holding two substrates.

FIG. 16A is a three dimensional view of a chamber suitable for heating and/or cooling large glass substrates.

FIG. 16B is a cross sectional view of the heating/cooling cassette of FIG. 16A.

FIG. 17A is a three dimensional view of a heating/cooling chamber for large glass substrates.

FIG. 17B is a cross-sectional view of the cassette of FIG. 17A.

FIG. 18A is a three dimensional view of a load-lock/cooling chamber for large glass substrates.

FIG. 18B is a cross-sectional view of the load lock/cooling cassette of FIG. 18A.

Like reference symbols in the various drawings indicate like elements.

### DETAILED DESCRIPTION

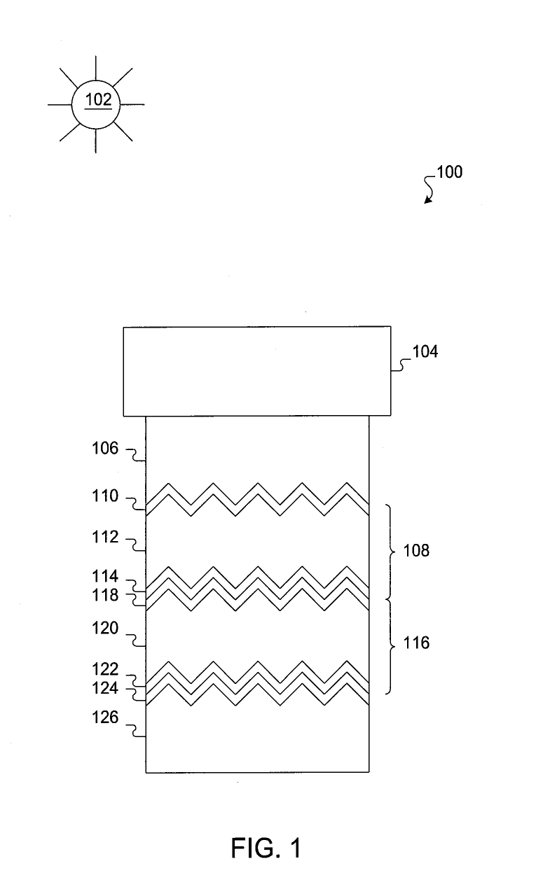

FIG. 1 is a schematic diagram of certain embodiments of a multi-junction solar cell 100 oriented toward the light or solar radiation 102. Solar cell 100 comprises a substrate 104, such as a glass substrate, polymer substrate, metal substrate, or other suitable substrate, with thin films formed thereover. The solar cell 100 further comprises a first transparent conducting oxide (TCO) layer 106 formed over the substrate 104, a first p-i-n junction 108 formed over the first TCO layer 106, a second p-i-n junction 116 formed over the first p-i-n junction 108, a second TCO layer 124 formed over the second p-i-n junction 116, and a metal back layer 126 formed over the second TCO layer 124. To improve light absorption by reducing light reflection, the substrate and/or one or more of thin films formed thereover may be optionally textured by wet, plasma, ion, and/or mechanical processes. For example, in the embodiment shown in FIG. 1, the first TCO layer 106 is textured and the subsequent thin films deposited thereover will generally follow the topography of the surface below it.

The first TCO layer 106 and the second TCO layer 124 may each comprise tin oxide, zinc oxide, indium tin oxide, cadmium stannate, combinations thereof, or other suitable materials. It is understood that the TCO materials may also include additional dopants and components. For example, zinc oxide may further include dopants, such as aluminum, gallium, boron, and other suitable dopants. Zinc oxide preferably comprises 5 atomic % or less of dopants, and more preferably comprises 2.5 atomic % or less aluminum. In certain instances, the substrate 104 may be provided by the glass manufacturers with the first TCO layer 106 already provided.

The first p-i-n junction 108 may comprise a p-type amorphous silicon layer 110, an intrinsic type amorphous silicon layer 112 formed over the p-type amorphous silicon layer 110, and an n-type microcrystalline silicon layer 114 formed over the intrinsic type amorphous silicon layer 112. In certain embodiments, the p-type amorphous silicon layer 110 may be formed to a thickness between about 60 Å and about 300 Å. In certain embodiments, the intrinsic type amorphous silicon layer 112 may be formed to a thickness between about 1,500 Å and about 3,500 Å. In certain embodiments, the n-type microcrystalline semiconductor layer 114 may be formed to a thickness between about 100 Å and about 400 Å.

The second p-i-n junction 116 may comprise a p-type microcrystalline silicon layer 118, an intrinsic type microcrystalline silicon layer 120 formed over the p-type microcrystalline silicon layer 118, and an n-type amorphous silicon layer 122 formed over the intrinsic type microcrystalline silicon layer 120. In certain embodiments, the p-type microcrystalline silicon layer 118 may be formed to a thickness between about 100 Å and about 400 Å. In certain embodiments, the intrinsic type microcrystalline silicon layer 120 may be formed to a thickness between about 10,000 Å and about 30,000 Å. In certain embodiments, the n-type amorphous silicon layer 122 may be formed to a thickness between about 100 Å and about 500 Å.

The metal back layer 126 may include, but not limited to a material selected from the group consisting of Al, Ag, Ti, Cr, Au, Cu, Pt, alloys thereof, or combinations thereof. Other processes may be performed to form the solar cell 100, such a laser scribing processes. Other films, materials, substrates, and/or packaging may be provided over metal back layer 126 to complete the solar cell. The solar cells may be interconnected to form modules, which in turn can be connected to form arrays.

Solar radiation 102 is absorbed by the intrinsic layers of the p-i-n junctions 108, 116 and is converted to electron-holes pairs. The electric field created between the p-type layer and the n-type layer that stretches across the intrinsic layer causes electrons to flow toward the n-type layers and holes to flow toward the p-type layers creating current. The first p-i-n junction 108 comprises an intrinsic type amorphous silicon layer 112 and the second p-i-n junction 116 comprises an intrinsic type microcrystalline silicon layer 120 because amorphous silicon and microcrystalline silicon absorb different wavelengths of solar radiation 102. Therefore, the solar cell 100 is more efficient since it captures a larger portion of the solar radiation spectrum. The intrinsic layer of amorphous silicon and the intrinsic layer of microcrystalline are stacked in such a way that solar radiation 102 first strikes the intrinsic type amorphous silicon layer 112 and then strikes the intrinsic type microcrystalline silicon layer 120 since amorphous silicon has a larger bandgap than microcrystalline silicon. Solar radiation not absorbed by the first p-i-n junction 108 continues on to the second p-i-n junction 116.

The solar cell 100 does not need to utilize a metal tunnel layer between the first p-i-n junction 108 and the second p-i-n junction 116. The n-type microcrystalline silicon layer 114 of the first p-i-n junction 108 and the p-type microcrystalline silicon layer 118 has sufficient conductivity to provide a tunnel junction to allow electrons to flow from the first p-i-n junction 108 to the second p-i-n junction 116.

It is believed that the n-type amorphous silicon layer 122 of the second p-i-n junction 116 provides increased cell efficiency since it is more resistant to attack from oxygen, such as the oxygen in air. Oxygen may attack the silicon films and thus forming impurities which lower the capability of the films to participate in electron/hole transport therethrough.

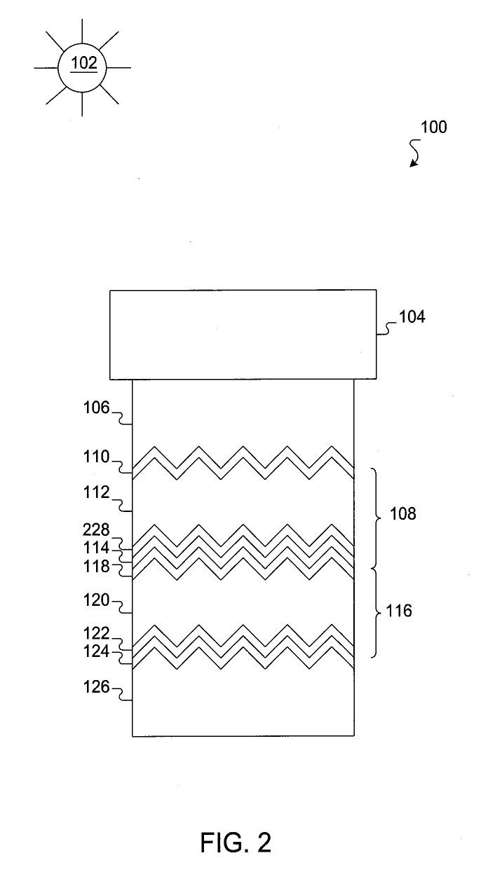

FIG. 2 is a schematic diagram of the multi-junction solar cell 100 of FIG. 1 further comprising an n-type amorphous silicon buffer layer 228 formed between the intrinsic type amorphous silicon layer 112 and the n-type microcrystalline silicon layer 114. In certain embodiments, the n-type amorphous silicon buffer layer 228 may be formed to a thickness between about 10 Å and about 200 Å. It is believed that the n-type amorphous silicon buffer layer 228 helps bridge the bandgap offset that is believed to exist between the intrinsic type amorphous silicon layer 112 and the n-type microcrystalline silicon layer 114. Thus it is believed that cell efficiency is improved due to enhanced current collection.

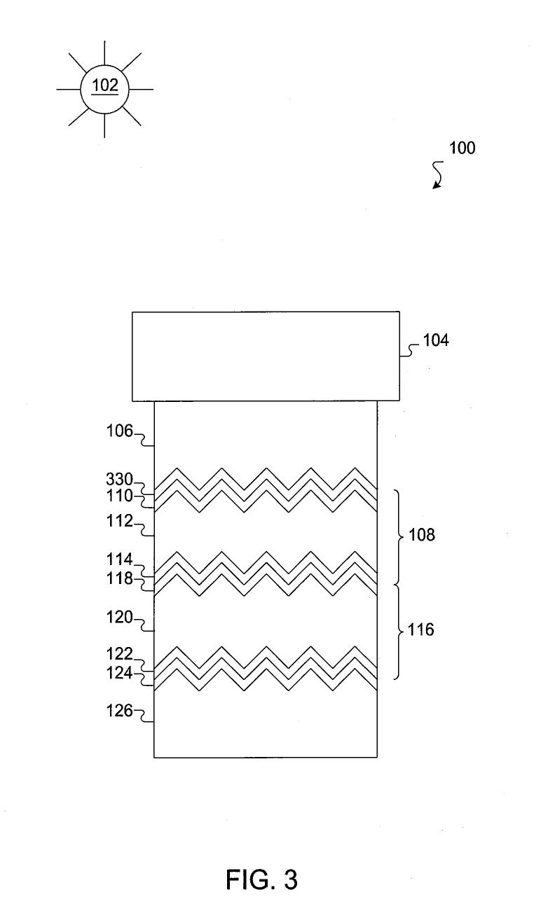

FIG. 3 is a schematic diagram of the multi-junction solar cell 100 of FIG. 1 further comprising a p-type microcrystalline silicon contact layer 330 formed between the first TCO layer 106 and the p-type amorphous silicon layer 110. In certain embodiments, the p-type microcrystalline silicon contact layer 330 may be formed to a thickness between about 60 Å and about 300 Å. It is believed that the p-type microcrystalline silicon contact layer 330 helps achieve low resistance contact with the TCO layer. Thus, it is believed that cell efficiency is improved since current flow between the p-type amorphous silicon layer 110 and the zinc oxide first TCO layer 106 is improved. It is preferred that the p-type microcrystalline silicon contact layer 330 be used with a TCO layer comprising a material that is resistant to a hydrogen plasma, such as zinc oxide, since a large amount of hydrogen is used to form the contact layer. It has been found that tin oxide is not suitable to be used in conjunction with the p-type microcrystalline silicon contact layer since it is chemically reduced by the hydrogen plasma. It is further understood that the solar cell 100 may further comprise an optional n-type amorphous silicon buffer layer formed between the intrinsic type amorphous silicon layer 112 and the n-type microcrystalline semiconductor layer 114 as described in FIG. 2.

Solar cells as described above are typically manufactured as large substrates, and then cut to a desired size. Substrates having a surface area of 10,000 cm² or more, for example 25,000 cm² or more, 40,000 cm² or more, or 55,000 cm² or more, may be processed using embodiments described herein.

FIG. 6 is a perspective view of a process system 600 having multiple vertical processing chambers. The process system 600 includes a transfer chamber 602 and eleven process chambers 604-624. In other embodiments, the process system 600 includes 5-15 process chambers, preferably 8-13 process chambers, more preferably 11, based on the footprint of the process chambers and the amount of space available for the process system 600. Vertical processing chambers reduce the overall size of the process system 600 and allow the system to include more processing chambers, which increases throughput. In some embodiments, the process system 600 is the same system as the process system 500.

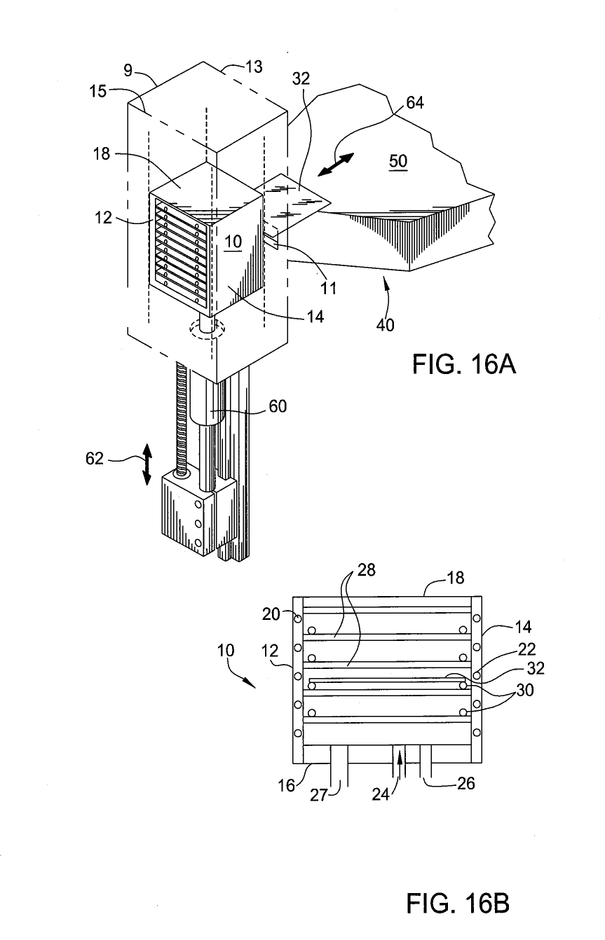

The process system 600 includes two preheat chambers 604 and 624, two anneal chambers 606 and 622, and seven CVD chambers 608-620. In some embodiments, the process system 600 includes a load lock chamber (not shown) that preheats substrates that come into the process system 600 and cools down substrates that have already been processed in the process system 600. One embodiment of a heating/cooling cassette will be described with reference to FIGS. 16 and 16A.

In certain embodiments, the process chambers 604-624 include chemical vapor deposition (CVD) chambers. CVD chambers can in certain embodiments deposit silicon, germanium, gallium, copper, aluminum, tin, oxides, zinc, or silver onto the substrates. In some embodiments, in order to deposit films with the desired properties, dopants are added to the processing gases. Doping agents include phosphorus, boron, and compounds such as diborane (B2H6). In some embodiments, the process chambers 604-624 include physical vapor deposition (PVD) chambers. PVD chambers can in certain embodiments deposit zinc, copper, silver, aluminum, chromium, zinc oxide, indium tin oxide, or germanium. The process chambers 604-624 can include one or more anneal chambers used to treat substrates before or after deposition of materials onto the substrate. In certain embodiments, the process system 600 includes one or more etch chambers. The etch chambers can in certain embodiments remove films deposited in other process chambers 604-624 or in other systems. The process system 600 can include preheat and cool down chambers that respectively heat substrates up before processing and cool substrates down after processing. In some embodiments, one or more cleaning chambers are included in the process chambers 604-624. Cleaning chambers remove particles from substrates in order to prevent contamination. Sources of particle contamination include but are not limited to movement of substrates throughout the process system 600 and the ambient environment outside of the process system 600, etching chambers, and laser scribing systems.

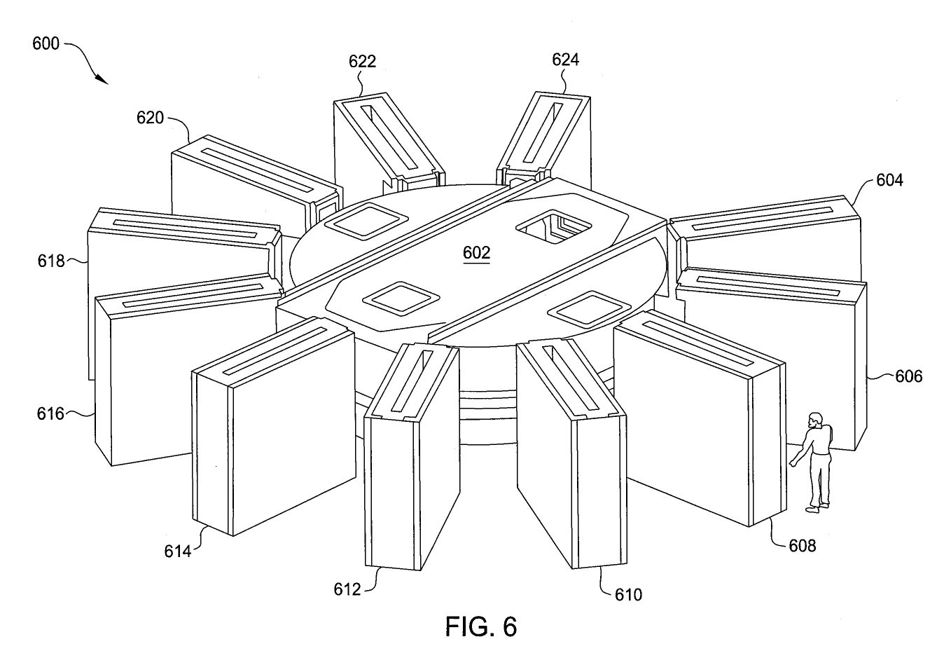

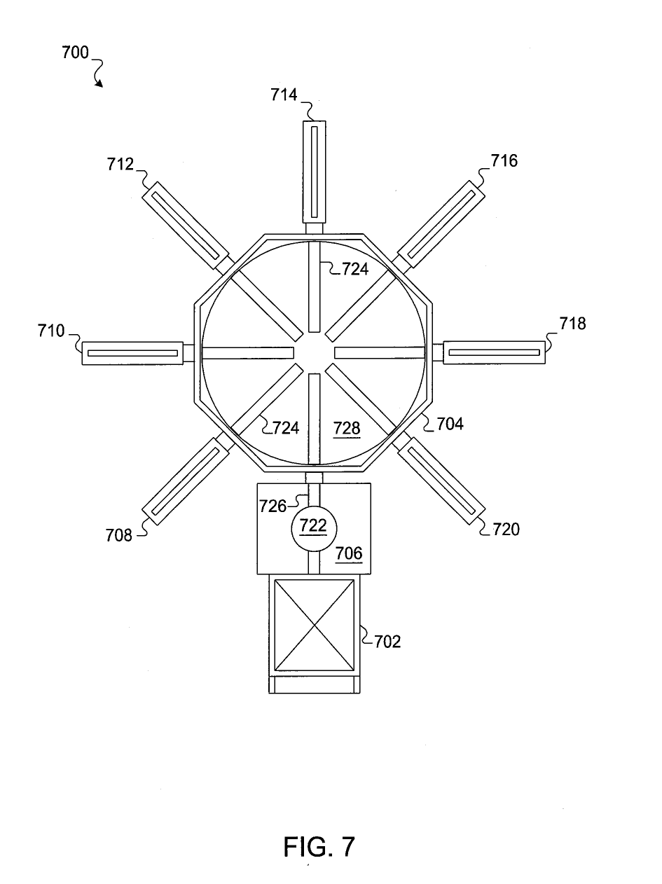

FIG. 7 is a top down view of a process system 700. The process system 700 includes a load lock chamber 702, a transfer chamber 704, a framing chamber 706, and seven process chambers 708-720. The process chambers 708-720 may be plasma processing chambers with a single processing volume separated into two processing regions by one or more substantially vertical antennas, each processing region configured to accept a substrate in a substantially vertical orientation. In some embodiments, the process chambers 708-720 include CVD chambers, such as the PECVD chamber 400, PVD chambers, anneal chambers, etch chambers, substrate cleaning chambers, preheat chambers, and/or cool down chambers, as described in reference to FIG. 6.

The load lock chamber 702 receives substrates from the ambient environment outside of the process system 700 in a vertical position. A glass loader robot (not shown) located in the ambient environment loads substrates into the load lock chamber 702. The glass loader robot uses mechanical grips to pick up substrates from conveyors located on the factory floor, rotate the substrates into a vertical position, and place the vertical substrates into the load lock chamber 702. The mechanical grips on the glass loader robot touch the edges and a small portion of the front surface of the substrates in order to rotate the substrates safely with as little damage to the front side of the substrates as possible. In other embodiments, the glass loader robots use vacuum suction on the backside of the substrates in order to pick up and rotate substrates for placement into the load lock chamber 702. The use of vacuum suction reduces the chance of contaminating the front side of the substrates.

In some embodiments, the load lock chamber 702 includes two chambers. Substrates are loaded into the process system 700 in one chamber and unloaded from the process system 700 in the other chamber. In certain embodiments, the loading chamber preheats substrates before the substrates are introduced into the process chambers 708-720. The preheat chamber brings the substrates up to or near processing temperatures, such between about 100° C. and about 500° C., preferably between about 200° C. and about 300° C. For processes performed at or near room temperature, the preheat chamber may be omitted. In certain embodiments, the chamber used to unload substrates from the process system 700 cools the substrates down to or near the temperature of the ambient environment. The height of the load lock chamber 702 (e.g., 2.4 meters) is shorter than the depth of the load lock chamber 702 (e.g., 2.8 meters) allowing substrates to be loaded into the load lock chamber 702 with the short end forward. In other embodiments, the height of the load lock chamber 702 (e.g., 3.4 meters) is greater than the depth of the load lock chamber (e.g., 3.2 meters).

The framing chamber 706 includes a vacuum robot 722. The vacuum robot 722 picks up substrates located in the load lock chamber 702 and mounts the substrates onto frames used to move the substrates through the process system 700. The vacuum robot 722 uses vacuum suction on the wafer backside in order to pick up and mount the substrates. In other embodiments, the substrates move through the process system 700 independently without frames. In certain embodiments, substrates are loaded into the process system 700 in a horizontal position. The vacuum robot 722 rotates substrates located in a horizontal position to a vertical position before mounting onto the frame. The frames may be larger, smaller, or approximately the same size as the substrates.

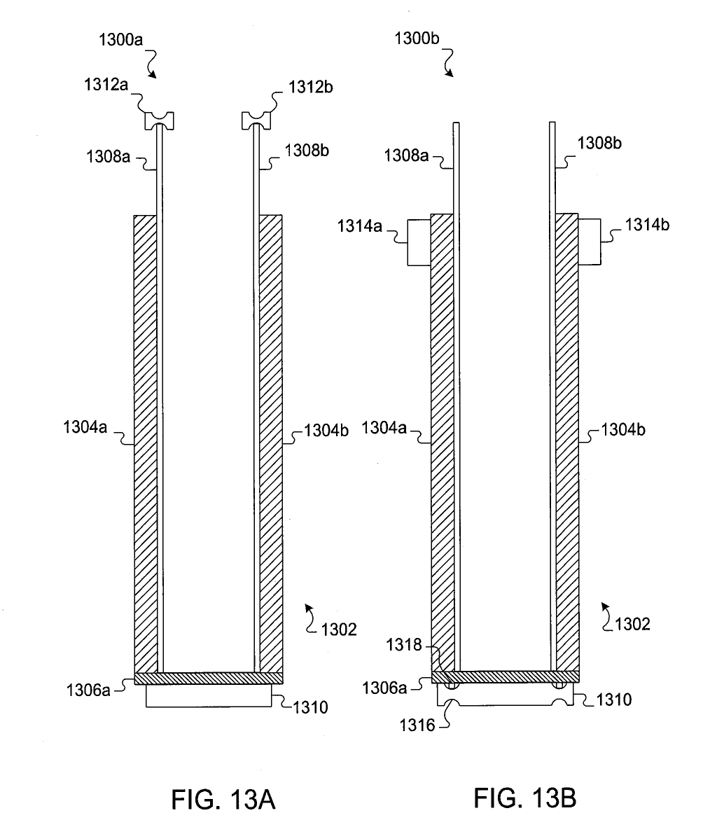

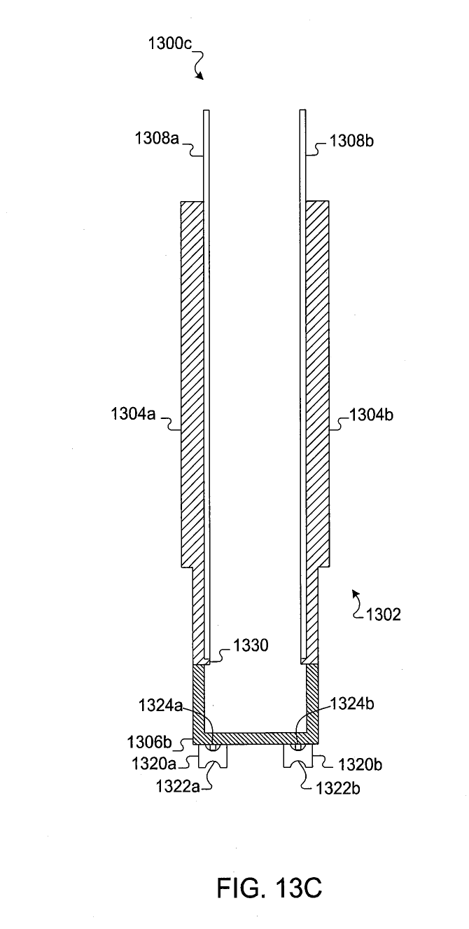

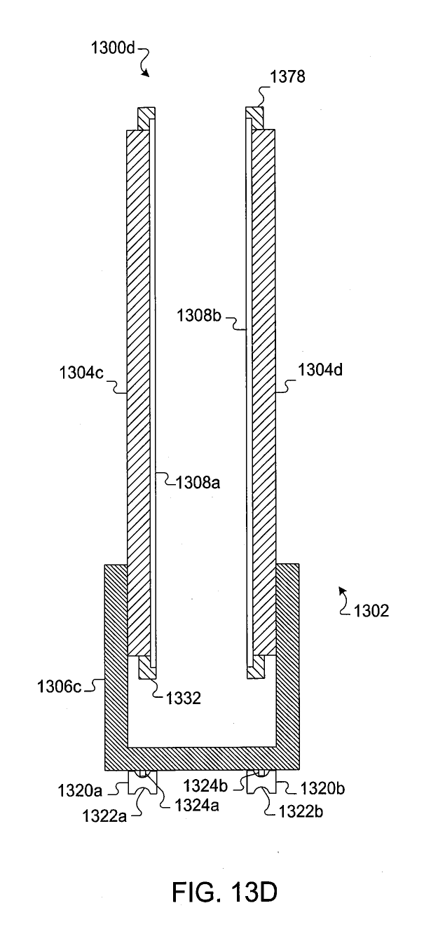

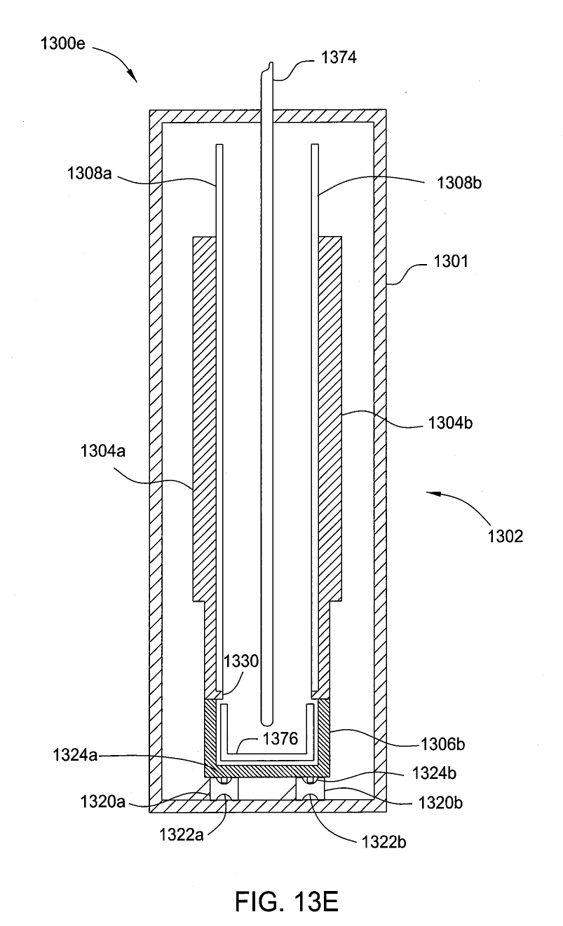

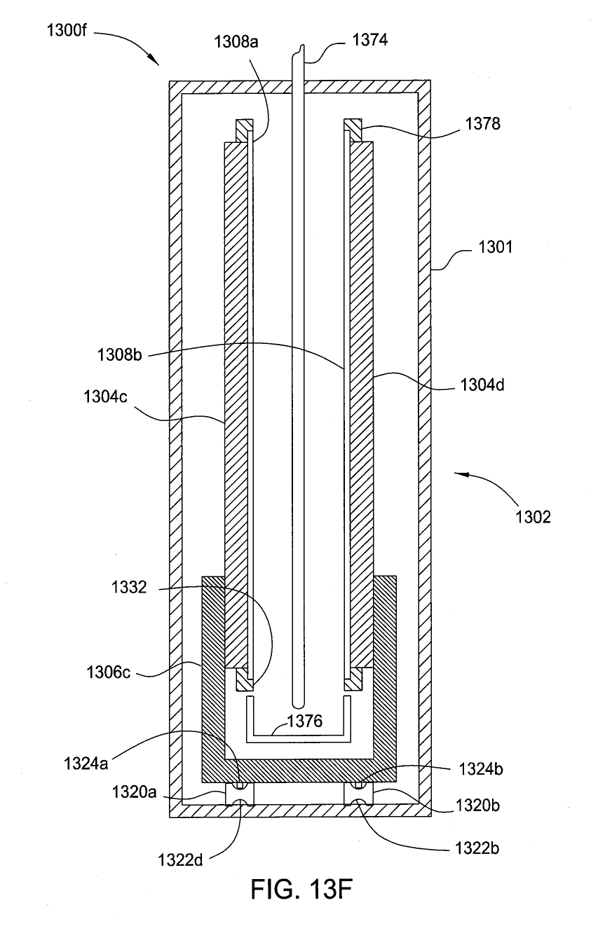

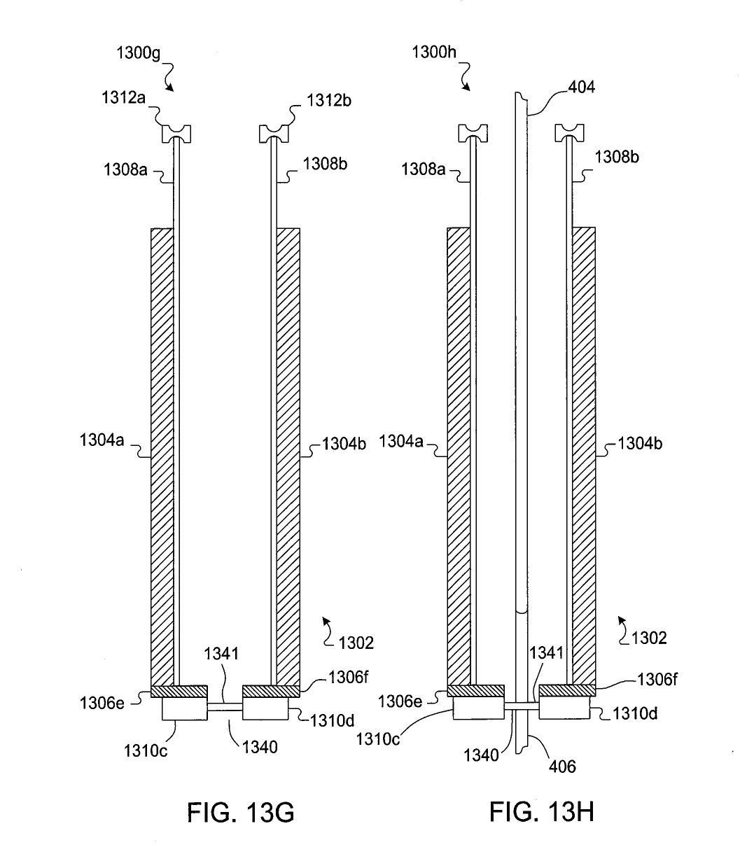

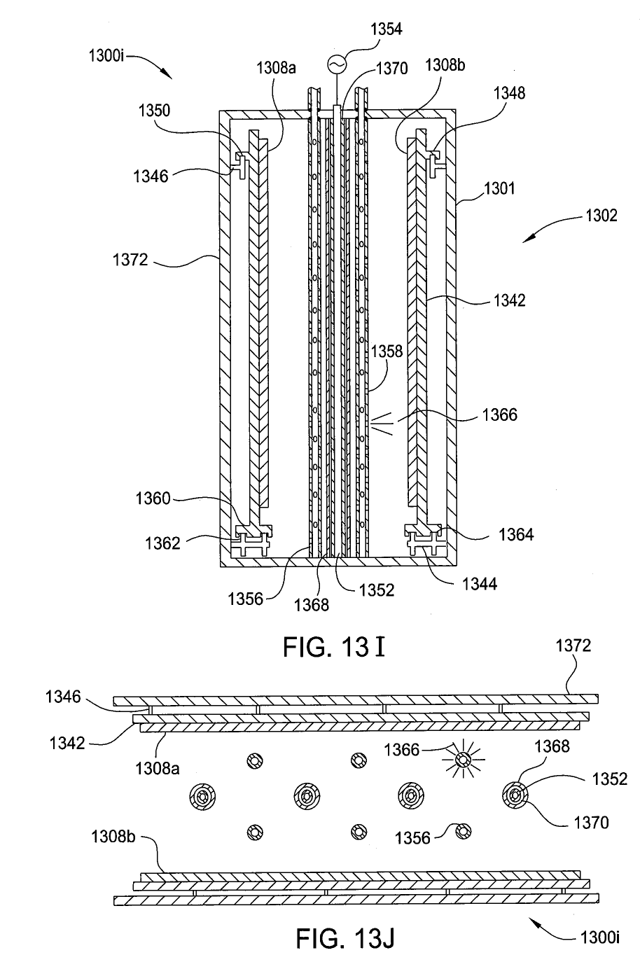

In one embodiment, the frames may be smaller than the substrates. The smaller size reduces deposition of films onto the frames and reduces the need to clean the frames. Reduced cleaning time increases throughput in the process system 700. In some embodiments, the frames have four upper and four lower fingers that help hold the substrates in place. In other embodiments, the frames have fingers on the top, bottom, and sides of the substrate to hold the substrate in place (e.g., four fingers on each side of the substrate). Two single substrate frames may optionally connect with an aluminum cross member below the substrates to form a dual substrate frame as discussed below with reference to FIGS. 13A-D. In certain embodiments, the two single substrate frames are connected both above and below the substrates when forming a dual substrate frame. The dual substrate frames hold the substrates in a face-to-face position for processing in the process chambers 708-720. In some embodiments, the substrates are mounted in a back-to-back position for processing the process chambers 708-720. The frames may use electrostatic charge to hold the substrates in place with an electrostatic chuck (ESC) located inside of the frame as described with reference to FIGS. 13A and 13D. The ESC is described below with reference to FIGS. 37-38. In other embodiments, the frames use vacuum suction to hold substrates in place during movement through the process system 700. In some embodiments, the frames use directional adhesive to hold the substrates in place without contaminating the substrates. The frames are made from or coated with anodized aluminum in order to increase the durability of the frames. The frames can alternatively be made from ceramic material.

In certain embodiments, the load lock chamber 702 includes two vacuum robots 722, one for each of the single substrate frames. The robots 722 use vacuum pressure to hold the substrates in place during rotation and placement on frames. In other embodiments, the robots 722 use electrostatic charge created by a bipolar electrostatic chuck (ESC) or monopolar ESC. In some embodiments, the robots 722 use mechanical grips to rotate and frame the substrates. The mechanical grips contact the wafer backside and edges. In some embodiments, the mechanical grips contact the front side of the substrates in order to provide additional support.

The transfer chamber 704 facilitates movement of substrates between the framing chamber 706 and one or more of the process chambers 708-720. The transfer chamber 704 receives substrates from and introduces substrates into all of the chambers 706-720 with the same interface (e.g., the transfer chamber 704 can not tell the difference between the framing chamber 706 and the process chambers 708-720). The transfer chamber 704 includes eight conveyors 724 to move substrates into and out of the chambers 706-720. A conveyor 726, located in the framing chamber 706, slides substrate frames onto one of the conveyors 724 in the transfer chamber 704. In the case of unconnected single substrate frames, the conveyors 724 of the transfer chamber 704 may handle two frames simultaneously, with the substrate on each frame facing the substrate on the other frame. After substrates are processed, the conveyor 726 receives the pair of substrate frames from the conveyors 724. The vacuum robot 722 removes the substrates from the substrate frames and places the substrates into the load lock chamber 702. The process chambers 708-702 include similar conveyors (not shown) for movement of the substrate frames, connected as a dual frame, as an unconnected pair of frames, or independently as individual frames, throughout the process system 700. In other embodiments, rollers are used to move the dual substrate frames though the process system 700.

The transfer chamber 704 includes a turntable 728 that rotates around the central vertical axis of the transfer chamber 704. Rotation of the turntable 728 lines up the conveyors 724 with the conveyors located in the chambers 706-720. The turntable 728 indexes the number of degrees of rotation between each of the chambers 706-720 such that the turntable 728 rotates 45° in order to move a dual substrate frame or pair of substrate frames from one chamber to the chamber directly next to it. The index can be from 10-45°, preferably 22.5-45°, more preferably 45°. In other embodiments, software controlling the process system 700 tracks of the amount of time needed to rotate the turntable 728 between the chambers 706-720 (e.g., when it takes the same amount of time to rotate between any two adjacent chambers). In some embodiments, the software tracks varying times or degrees of rotation such that any two adjacent chambers can have varying distances between the openings of the chambers. This allows chambers of different sizes to be attached to the process system 700. Varying distances also allows the chambers to be attached to the process system 700 in order to maximize the use of the space on the factory floor. When one of the conveyors 724 is supporting a frame and is in line with one of the chambers 706-720, the frame slides into the chamber using the conveyor 724 and a matching conveyor 726 (not shown in the process chambers 708-720). In other embodiments, shuttles with wheels move the substrate frames in the transfer chamber 704 between the chambers 706-720. The shuttles include side supports to help stabilize the substrate frames and prevent the frames from tipping. In some embodiments, the shuttles move along tracks while moving the frames between the chambers 706-720. In other embodiments, robots located on the turntable 728 in the transfer chamber 704 move the substrate frames between the chambers 706-720. The turntable 728 includes side or top supports for the substrate frames in addition to the bottom mechanism (e.g., the conveyors 724-726) in order to help stabilize the substrate frames. In some embodiments, the conveyors 724-726 include motorized wheels below the substrate frames and non-motorized wheels above the frames to hold each substrate frame upright.

The process chambers 708-720 can include capacitively coupled plasma (CCP) chambers, inductively coupled plasma (ICP) chambers, microwave chambers, CVD chambers, PVD chambers, preheat chambers, cool down chambers, and/or anneal chambers. In certain embodiments, CCP and/or microwave chambers are used for PECVD processes for deposition of thin films onto substrates. In other embodiments, ICP chambers are used to create high density plasma (HDP) for deposition of films onto substrates where there is reduced contamination on the electrodes used to form the plasma. In some embodiments, the process chambers 708-720 process two substrates in a face-to-face position at the same time using a single plasma field. The process chambers 708-720 form plasma between two face-to-face substrates and deposit films on both of the substrates at the same time. In other embodiments, substrate frames that hold two substrates in a back-to-back position are introduced into the process chambers 708-720. The process chambers 708-720 create two plasma fields in order to deposit films onto substrates held in a back-to-back position. In certain embodiments, the process chambers 708-720 process two pairs of substrates at a time (e.g., two pairs of substrates held in a dual substrate frame or on separate unconnected frames).

The process chambers 708-720 have a mask (not shown) that prevents deposition of materials on the dual substrate frame. A lower mask prevents deposition of process gases onto the aluminum cross member located below the two single substrate frames. In some embodiments, an upper mask prevents deposition of material onto the upper connection of the dual substrate frame. In some embodiments, additional masks are used to prevent deposition of material onto the sides of the dual substrate frame. In certain embodiments, the masks are cantilever mounted to the side of the process chambers 708-720. Alternatively, the masks can be mounted onto the top or the bottom of the process chambers 708-720.

Once processing of two substrates in the substrate frame is complete, the transfer chamber 704 moves the substrate frames back to the framing chamber 706. The robots 722 in the framing chamber 706 remove the two substrates from the substrate frames and place the substrates into the load lock chamber 702. In some embodiments, the robots 722 load the substrates into a cool down chamber located in the load lock chamber 702. The substrates can be unloaded from the load lock chamber 702 into the ambient environment outside of the process system 700 for processing in another system (e.g., another process system 700). Once deposition of films onto substrates is complete, the substrates can be moved into simulation systems for testing.

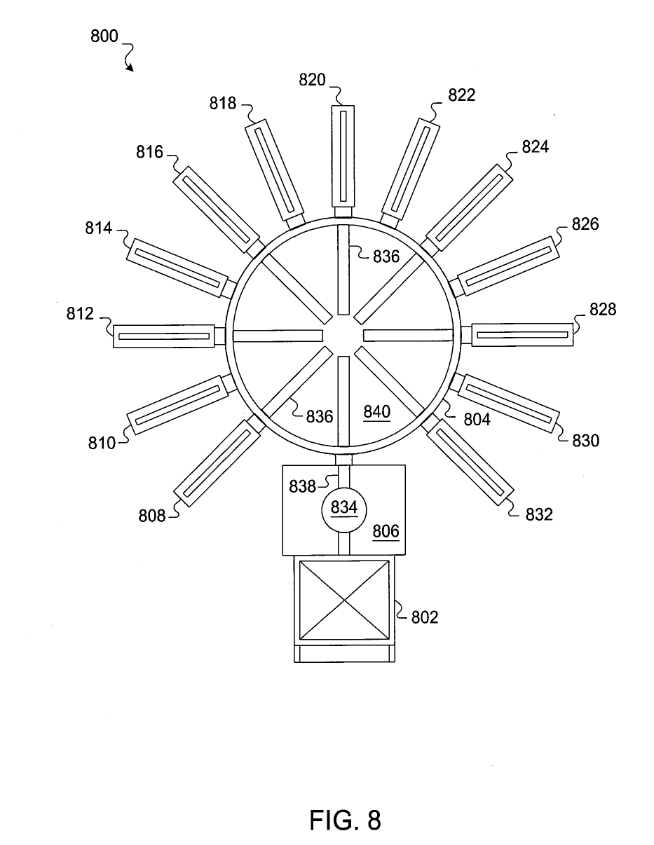

FIG. 8 is a top down view of a process system 800. The process system 800 can be the same as any of the process systems 500, 600, and/or 700. The process system 800 includes a load lock chamber 802, a transfer chamber 804, a framing chamber 806, and thirteen vertical substrate process chambers 808-832. In some embodiments, the production line that includes the process system 800 processes substrates that are about 1 meter square or more. In other embodiments, the substrate sizes range from about 1.4 meters square to about 10.03 meters square.

The transfer chamber 804 has a circular shape that allows modular connection of the process chambers 808-832. This arrangement allows additional process chambers to be attached to the transfer chamber 804 in order to increase throughput. Chambers are removed from the transfer chamber 804 in order to decrease throughput or for maintenance or other upkeep. The circular shape of the process system 800 allows any number of process chambers to be attached to the process system 800 in addition to the load lock chamber, space permitting. In some embodiments, more than one load lock chamber 802 and framing chamber 806 pair are attached to the transfer chamber 804 in order to increase throughput. Substrates are loaded into the process system 800 with a first load lock chamber and attached to a frame in a first framing chamber. A second framing chamber removes substrates from the frames and places the substrates into a second load lock chamber for unloading from the process system 800.

The number of process chambers attached to the transfer chamber 804 varies depending on the desired processing in the system 800. In some embodiments, additional process chambers are attached to the process system 800 and used during deposition of intrinsic layers for solar cells. In some embodiments, the distance between the process chambers 808-832 around the circumference of the transfer chamber 804 is between about 10 cm and about 200 cm, preferably between about 50 cm and about 100 cm.

A vacuum robot 834 located in the framing chamber 806 loads substrates onto single or dual substrate frames (not shown) for transfer throughout the process system 800. In certain embodiments, two vacuum robots 834 are located in the framing chamber 806 in order to load two substrates at a time onto separate substrate frames. One robot 834 is mounted onto the top of the framing chamber 806 and the other robot 834 is mounted to the bottom of the framing chamber 806. In some embodiments, this allows one robot 834 to load substrates into a frame from the top and the other robot 834 to load substrates into a frame from the bottom. In other embodiments, both substrates are loaded onto frames from the top. Alternatively, both substrates can be loaded onto frames from the bottom by the robots 834. The vacuum robot 834 picks up and moves substrates in a similar manner as discussed above with regard to the vacuum robot 722 in reference to FIG. 7. In some embodiments, the substrate frames hold substrates in place using electrostatic charge. The vacuum robot 834 loads a substrate onto a frame and the framing chamber 806 applies voltage to the frame creating an electrostatic charge that holds the substrate in place on the frame. In other embodiments, the substrate frames hold each substrate in place using vacuum suction.

Eight conveyors 836 move frames from the framing chamber 806 into the transfer chamber 804. A conveyor 838 located inside the framing chamber 806 helps move the frame onto the conveyors 836. In some embodiments, the conveyors 836 and/or the conveyor 838 are a pair of conveyors. One set of conveyors is mounted on the bottom of the process system 800 and one set is mounted on the top (e.g., one conveyor is on the floor of the framing chamber 806 and another conveyor is on the ceiling). A turntable 840 located in the transfer chamber 804 facilitates movement of the frames between the framing chamber 806 and the process chambers 808-832. The turntable 840 rotates about a vertical axis that runs through the center of the transfer chamber 804. The turntable 840 indexes the number of degrees needed to move substrate frames between two chambers 806-832. The turntable 840 rotates a specific number of degrees in order to transfer the substrate frames between any two of the chambers 806-832. The degree of rotation between any two adjacent chambers can vary depending on chamber size and the number of chambers attached to the transfer chamber 804. In other embodiments, the degree of rotation between each of the chambers 806-808 is the same.

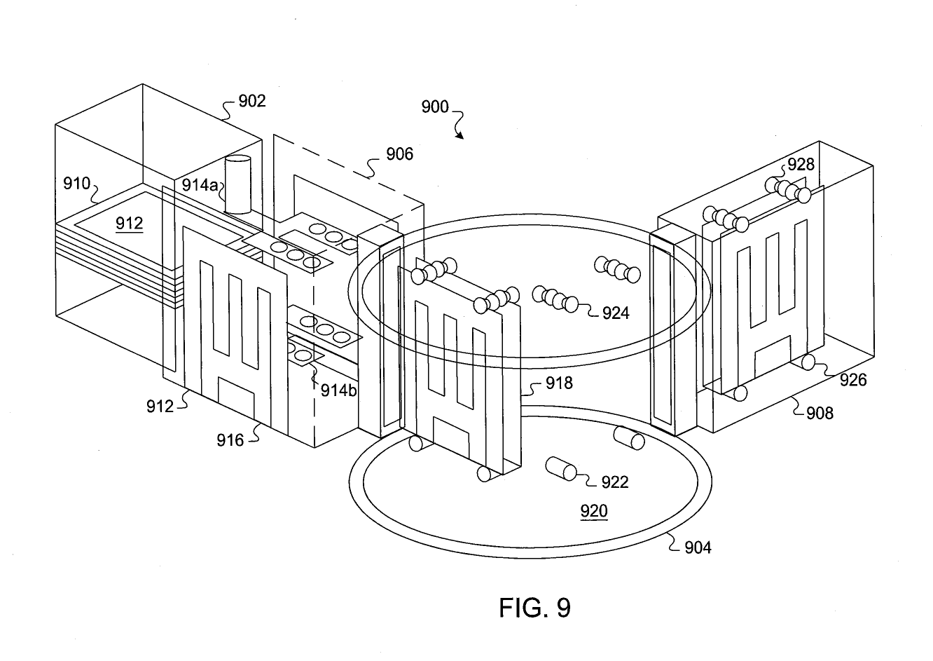

FIG. 9 is a cross sectional view of a process system 900 that includes a load lock chamber 902, a transfer chamber 904, a framing chamber 906, and a process chamber 908. In some embodiments, the process system 900 is the same system as the process system 500, the process system 700, and/or the process system 800. The process system 900 can deposit layers on semiconductor substrates for solar panels or thin film transistors. The process system 900 receives substrates in a horizontal position and rotates the substrates into a vertical position for processing. In some embodiments, the process system 900 receives substrates in a vertical position for vertical processing. Alternatively, the process system 900 can receive substrates in a horizontal position from the ambient environment outside of the process system 900 for horizontal processing in the process system 900. In certain embodiments, there are 4-25 process chambers attached to the transfer chamber 904, for example 8-17 process chambers, such as 13 process chambers.

The load lock 902 includes multiple shelves 910 that physically support substrates. The shelves have edges that touch the edges of substrates 912 and a center portion that touches the center of the substrates' 912 backsides. Multiple substrates 912 are loaded into the load lock 902 and placed onto the shelves 910 by a glass loader robot (not shown) located on the factory floor. Each of the one or more shelves 910 includes an opening, and edges for loading and unloading of the substrates 912 into and out of the load lock chamber 902. Substrates are loaded into the load lock chamber 902 by a glass loader robot in a horizontal position. In other embodiments, the substrates 912 are loaded and unloaded from the load lock chamber 902 in a vertical position.

In certain embodiments, the load lock chamber 902 preheats substrates 912 before processing or cools down the substrates 912 after processing. In some embodiments, electric resistor heating coils in the walls of the load lock chamber 902 preheat substrates 912 before processing or cooling channels cool substrates 912 down to ambient temperature after processing. In some embodiments, cooling gas flows across the substrates 912 to cool the substrates 912 down to ambient temperature. In other embodiments, cooling gas or liquid flows through the walls of the load lock chamber 902 in order to cool down the substrates 912 and does not flow across the surface of the substrates 912. In certain embodiments, the load lock chamber 902 is the same as the load lock chamber 702 and the load lock chamber 802. In some embodiments, the load lock chamber 902 includes multiple chambers such that the load lock chamber 902 can preheat and cool down substrates at the same time. The load lock chamber 902 includes an upper compartment (not shown) that preheats the substrates 912 (e.g., to processing temperature) and a lower compartment (not shown) that cools the substrates 912 after processing (e.g., to the ambient temperature outside of the process system 900). In some embodiments, the process system 900 includes more than one load lock. The process system 900 can include an input load lock for loading substrates into the process system 900 and preheating of the substrates; and an output load lock for cooling of substrates and for unloading substrates from the process system 900 into the ambient environment outside of the process system 900.

The framing chamber 906 includes two robots 914a-b for mounting substrates 912 onto substrate frames 916. The robots 914a-b use electrostatic charge to pick up and mount the substrates 912 onto frames 916. Once the frames 916 securely hold the substrates 912, the electrostatic charge is removed from the robots 914a-b. In some embodiments, the two robots 914a-b use vacuum suction to move the substrates 912. Alternatively, the robots 914a-b can use grips to remove substrates 912 from the load lock chamber 902 and mount the substrates 912 onto the frames 916. Two substrates 912 are loaded onto two frames 916 and then the two frames 916 optionally connect together with an anodized aluminum cross member below the substrates. In other embodiments, two frames 916 optionally attach together with an anodized aluminum cross member at the bottom of the frame 916 before loading of two substrates onto the frames 916. In certain embodiments, two or more frames 916 optionally connect together at the bottom of the frames 916. In some embodiments, the two single substrate frames 916 optionally attach with additional cross members on both of the sides. Alternatively, two single substrate frames 916 can attach with cross members on the bottom and both of the sides. Two single substrate frames 916 attach together to form a dual substrate frame 918. In some embodiments, when the two robots 914a-b mount substrates onto the dual substrate frame 918, the framing chamber 906 is a different size (e.g., larger) than a framing chamber where substrates are mounted onto single substrate frames 916. In some embodiments, the frames 916 holds the substrates 912 in place with vacuum suction on the backside of the substrates. In other embodiments, the frames 916 hold substrates 912 in place with one or more electrostatic chucks and support fingers. Alternatively, the dual substrate frame 918 can hold substrates 912 in place using grips that hold on to the back and sides of the substrates 912. In certain embodiments, the glass loader robot located on the factory floor mounts the substrates 912 onto dual substrate frames 918 located in the load lock chamber 902. If the frames 916 are not attached to form the dual substrate frame 918, the frames 916 may travel through the system as a pair.

The cross member connects to the single substrate frames 916 with clips to hold the single substrate frames 916 in place. In certain embodiments, the cross member is manufactured such that the cross member is welded onto two single substrate frames 916 and the cross member has an adjustable width. The cross member expands to allow the robots 914a-b to mount substrates 912 onto the frames 916. Once substrates 912 are mounted onto the frames 916, a stepper motor contracts the width of the cross member so that the distance between the two substrates mounted on the frames 916 is between about 10 cm-15 cm, more preferably between about 11 cm-13 cm. In some embodiments, the frames 916 can pivot about the horizontal axis created by where they join the cross member. Pivoting the frames 916 allows mounting of substrates 912 without the need to expand the cross member as much as needed otherwise. In certain embodiments, the frames 916 pivot to a horizontal position such that horizontal substrates in the load lock chamber 902 roll directly onto the frames 916. The frames 916 pivot around the horizontal axis using bearings located where the cross member physically connects to the frames using a hinge.

The transfer chamber 904 includes a turntable 920 that rotates around the central vertical axis of the transfer chamber 904. The turntable 920 moves substrate frames 916 between the chambers attached to the transfer chamber 904. Bottom rollers 922 and top rollers 924 located in the transfer chamber 904 physically contact and move the substrate frames 916 into and out of the transfer chamber 904. In some embodiments, the turntable 920 includes both a bottom and top portion attached to the bottom rollers 922 and top rollers 924 respectively. The bottom rollers 922 are motorized in order to physically move the frames 916 and the top rollers 924 are passive (e.g., non-motorized) and assist in keeping the frames 916 upright. Rollers with the same function as the rollers 922 and 924 are located in the framing chamber 906. Once the frames 916 are loaded with two substrates in the framing chamber 906, movement of the rollers located in the framing chamber 906 transfer the frames 916 onto the rollers 922 located in the transfer chamber 904. In other embodiments, both the bottom rollers 922 and the top rollers 924 are motorized. In certain embodiments, conveyor belts are used instead of the bottom rollers 922 and/or the top rollers 924. In other embodiments, shuttles located in the transfer chamber 904 move the dual substrate frames between the framing chamber 906 and the one or more process chambers 908. Alternatively, tracks can be used for moving the frames 916 throughout the process system 900. In some embodiments, shuttles located on the tracks move between the one or more process chambers 908 and the framing chamber 906. In other embodiments, the frames 916 have wheels located on the bottom and top thereof. In still other embodiments, the frames 916 have a combination of wheels and magnets on the bottom and sides that facilitate movement through the process system 900 and keep the frames 916 upright.

In some embodiments, the turntable 920 has the same configuration as the turntable 728, and/or the turntable 840. The turntable 920 includes a motor that rotates the turntable 920 a specific number of degrees in order to move the dual substrate frame 918 between the chambers 906 and 908. The turntable 920 moves substrate frames 916 into and out of the framing chamber 906 and the process chambers 908 in the same way (e.g., with rollers). In some embodiments, software controlling the turntable 920 is designed such that the degree of rotation of the turntable 920 is small when moving the substrate frames 916 between two process chambers 908. The degree of rotation between the process chambers 908 and the framing chamber 906 is greater than the degree of rotation between two process chambers 908.

The substrate frames 916 move into the one or more process chambers 908 from the transfer chamber 904 in a similar manner to movement between the framing chamber 906 and the transfer chamber 904. Two bottom rollers 926 and four top rollers 928 located in the process chambers 908 help move the substrate frames 916 into the process chambers 908. In some embodiments, one or both sets of rollers 926 and 928 can be motorized. In some embodiments, a different number of bottom rollers 926 and top rollers 928 are used to move the substrate frames 916. The process chambers 908 can be PVD chambers, etch chambers, CVD chambers, anneal chambers, or preheat chambers, as discussed above with reference to FIG. 6. The one or more process chambers 908 process two substrates held in the substrate frames 916 at the same time. The substrate frames 916 hold the two substrates in a face-to-face position within the process chamber 908. Alternatively, the two substrates can be held in a back-to-back position within the process chamber 908. In some embodiments, the process chamber 908 holds more than one pair of frames 916, such as two pair, or three pair. After processing the substrates 912 in the process chambers 908 (e.g., a preheat chamber, three CVD chambers, and an anneal chamber) the substrate frames 916 move back into the transfer chamber 904. When processing is complete the turntable 920 rotates to line up the substrate frames 91 with the framing chamber 906. The framing chamber 906 removes the substrates 912 from the substrate frames 91 and loads the substrates 912 into the load lock chamber 902 or into a cool down chamber inside of the load lock chamber 902.

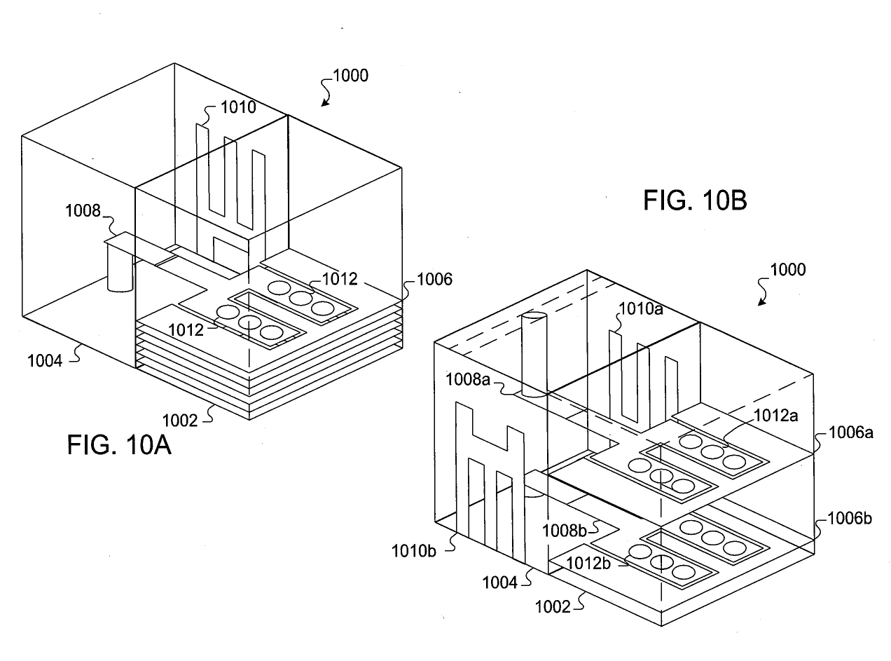

FIG. 10A shows a pair of chambers 1000 that include a load lock chamber 1002 and a substrate framing chamber 1004. In some embodiments, the process system 900 includes the pair of chambers 1000. The load lock chamber 1002 includes a plurality of shelves 1006. The shelves 1006 include edges that hold substrates in a horizontal position. In other embodiments, the shelves 1006 hold substrates in a vertical position.

The framing chamber 1004 includes a robot 1008 and a substrate frame 1010. The robot 1008 uses electrostatic charge created by an ESC 1012 to hold substrates in place. In other embodiments, the robot 1008 uses mechanical grips to pick up and move substrates. The mechanical grips can make contact with the substrates on the edge and backside of the substrates. In still other embodiments, the robot uses vacuum suction in order to pick up and move substrates. After picking up a substrate the robot 1008 moves vertically and/or horizontally in order to withdraw a substrate from the load lock chamber 1002 and move the substrate into the framing chamber 1004. The robot 1008 rotates the horizontal substrate into a vertical position for mounting onto the substrate frame 1010. In other embodiments, the robot 1008 does not need to rotate substrates positioned vertically in the load lock chamber 1002 and only mounts the vertical substrates onto the substrates frame 1010. The robot 1008 mounts substrates onto the substrate frame 1010 from the top. In other embodiments, the robot 1008 mounts substrates onto the substrate frame 1010 from the bottom. The substrate frame 1010 can hold substrates in place with mechanical grips, electrostatic charge, or vacuum suction, as discussed above with reference to the single substrate frames 916 in FIG. 9.

FIG. 10B is another embodiment of a pair of chambers 1000. In this embodiment, the framing chamber 1004 includes two robots 1008a-b and two substrate frames 1010a-b. The robots 1008a-b pick up substrates from one or more shelves 1006a-b respectively using electrostatic force and move the substrates into the framing chamber 1004. The robots 1008a-b include one or more electrostatic chucks 1012a-b respectively. The robots 1008a-b mount the substrates onto the substrate frames 1010a-b respectively. The robot 1008a mounts a substrate onto the substrate frame 1010a from the top and the robot 1008b mounts a substrate onto the substrate frame 1010b from the bottom. Mounting the substrates from opposite sides can increase throughput in a process system and reduce chamber size. The robots 1008a-b can be the same type of robot as the robot 1008. The robots 1008a and 1008b are the same type of robot (e.g., both robots 1008a-b are vacuum robots). In other embodiments, the robots 1008a and 1008b use different methods to pick up and move substrates. After substrates have been loaded onto the substrate frames 1010a-b, the two substrate frames 1010a-b may optionally connect to form a dual substrate frame, such as the dual substrate frame 918, or the substrate frames 1010a-b may be processed as an unconnected pair of frames.

All three substrate frames, 1010, 1010a, and 1010b, are designed differently. In some embodiments, the substrate frame 1010 has the same configuration as the substrate frames 1010a-b. In other embodiments, the substrate frame 1010 is different from the substrate frames 1010a-b (e.g., the frames use different methods to hold substrates in place and/or are designed and manufactured differently). In still other embodiments, the substrate frame 1010 has the same configuration as one of the substrate frames 1010a-b. The design of the substrate frame 1010 allows the frame 1010 to receive a single substrate and transfer the substrate throughout a process system, such as the process system 900. The design of the substrate frame 1010a takes into consideration that an overhead robot loads substrates onto the substrate frame 1010a and that the frame 1010a may be attached or connected to another substrate frame to form a dual substrate frame such as the dual substrate frame 918. The design of the substrate frame 1010b allows a robot (e.g., the robot 1008b) to load the substrate frame 1010b from below. If the substrate frames 1010a-b are to be connected, the robots 1008a-b mount substrates onto the substrate frames 1010a-b before connecting the substrate frames 1010a-b together. In other embodiments, the robots 1008a-b mount substrates onto the substrate frames 1010a-b after connection of the two frames 1010a-b.

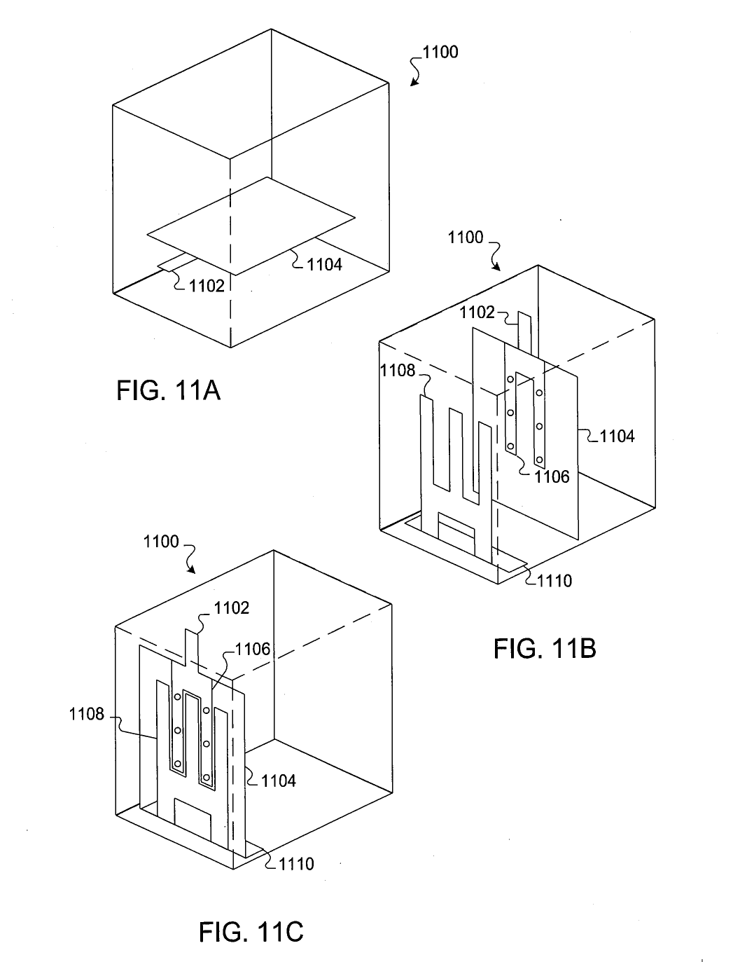

FIG. 11A is a perspective view of a re-orient and framing chamber 1100. In some embodiments, the re-orient and framing chamber 1100 is the same chamber as the framing chamber 706, the framing chamber 806, and/or the framing chamber 906. The re-orient and framing chamber 1100 includes a robot 1102 and a substrate 1104. The re-orient and framing chamber 1100 is attached to a load lock chamber and a transfer chamber (not shown). The robot 1102 extends into the load lock chamber in order to pick up the substrate 1104. The robot 1102 returns processed substrates to the load lock chamber after processing and a glass loader robot located in the ambient environment outside of the load lock chamber removes the substrates from the processing system. The load lock chamber holds the substrate 1104 in a horizontal position. When removing or returning substrates from the load lock the blade of the robot 1102 is on a horizontal plane in order to load and unload the horizontal substrates. In other embodiments, the load lock chamber holds substrates in a vertical position and the robot 1102 orients the robot blade in a vertical position when loading and unloading substrates.

FIG. 11B is a perspective view of the re-orient and framing chamber 1100 of FIG. 11A after the robot 1102 has rotated the substrate 1104 from a horizontal position into a vertical position around a horizontal axis. The horizontal axis is selected such that it allows the robot 1102 as much freedom of movement in the re-orient and framing chamber 1100 as possible. The robot 1102 includes a robot blade 1106. In certain embodiments, the axis is selected in the middle of the long side of the substrate 1104 (e.g., if the substrate is 2.2×2.6 meters, the axis is selected 1.3 meters from the short edge of the substrate). In other embodiments, the axis is positioned one third of the way from the short substrate edge closest to the distal end of the robot blade 1106 (e.g., about 0.8667 meters). The robot blade 1106 supports the bottom of the substrate 1104 and allows the robot 1102 to pick up and rotate the substrate 1104. The robot blade 1106 uses vacuum suction to hold the substrate 1104 in place while moving the substrate. In some embodiments, the robot blade 1106 uses electrostatic charge created by one or more electrostatic chucks to pick up and rotate the substrate 1104. In other embodiments, the robot blade 1106 attaches to the edges of the substrate 1104. To facilitate loading and unloading of the substrate 1104 from the load lock chamber, shelves in the load lock chamber have edges and a center that support the substrate 1104 backside and allow the robot blade 1106 to contact the substrate 1104 backside (as described with reference to FIGS. 10A-B).

The re-orient and framing chamber 1100 includes a single substrate frame 1108 and a frame cross member 1110. In some embodiments, the single substrate frame 1108 has the same configuration as the frame 916 and/or the frame 1010. Once the substrate 1104 is in a vertical position, the robot 1102 mounts the substrate 1104 onto the single substrate frame 1108. In some embodiments, the re-orient and framing chamber 1100 includes two single substrate frames that may optionally connect using the frame cross member 1110. If the substrate frames are to be connected, once substrates are mounted to each of the two single substrate frames, robots (not shown) pick up and connect the two substrates frames together using the frame cross member 1110.

In some embodiments, the load lock chamber holds substrates in a vertical position. When the substrate 1104 is removed from the load lock chamber in a vertical position, the robot 1102 mounts the substrate 1104 onto the single substrate frame 1108 without rotating it from a horizontal position to a vertical position.

FIG. 11C is a perspective view of the re-orient and framing chamber 1100 of FIG. 11B after the robot 1102 has mounted the substrate 1104 onto the single substrate frame 1108. The cross member 1110 helps hold the substrate 1104 in place by supporting the bottom edge of the substrate 1104. The single substrate frame 1108 holds the substrate 1104 in place with electrostatic charge. The single substrate frame 1108 contains an electrode used to create the electrostatic charge. Alternatively, the single substrate frame 1108 can include multiple electrodes such that the electrodes are sufficient to hold the substrate 1104 in place. The single substrate frame 1108 includes a bipolar electrostatic chuck. In other embodiments, the electrostatic chuck is monopolar. In some embodiments, the single substrate frame 1108 holds the substrate in place with vacuum suction. In other embodiments, the single substrate frame 1108 can hold the substrate 1104 in place by mechanically gripping the edges of the substrate 1104. The cross member 1110 and grips hold bottom and sides of the substrate 1104 respectively.

In certain embodiments, the re-orient and framing chamber 1100 includes two single substrate frames 1108. Once substrates are loaded onto two single substrate frames 1108, the two single substrate frames 1108 may optionally be connected physically with the cross member 1110. In other embodiments, the cross member 1110 optionally attaches two single substrate frames 1108 at the top of the single substrate frames. In some embodiments, the cross member 1110 optionally connects two single substrate frames 1108 at both the top and the bottom of the single substrate frame 1108 for added support. The single substrate frame 1108 is made from anodized aluminum. In other embodiments, the frame 1108 is made from ceramic material such as aluminum oxide or aluminum nitride.

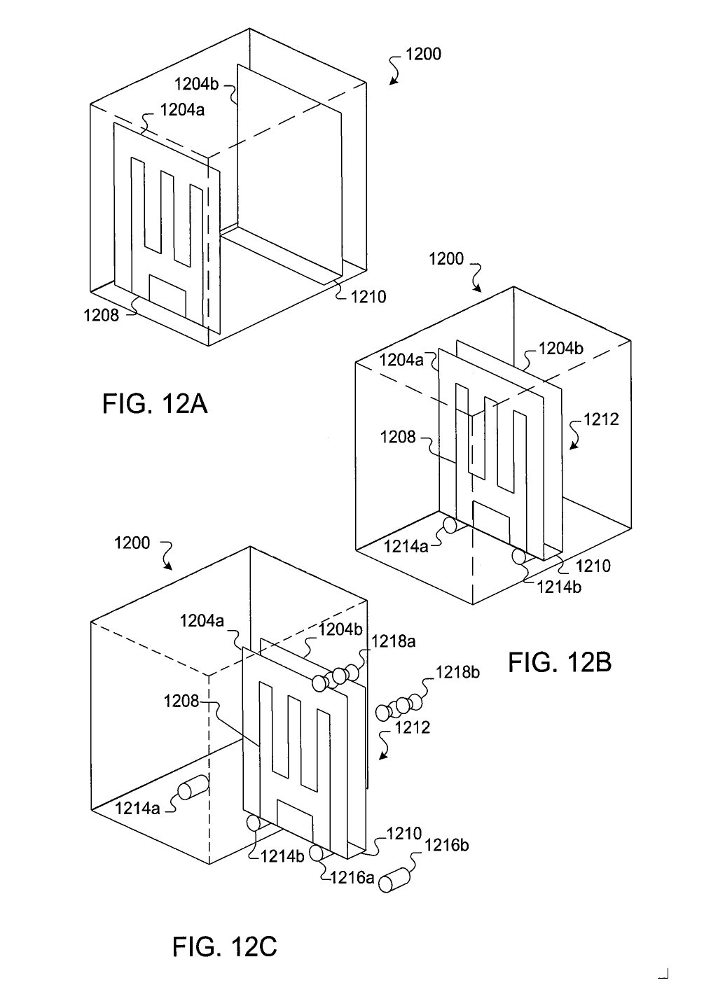

FIG. 12A is a perspective view of a framing chamber 1200. In some embodiments, the framing chamber 1200 is the same chamber as the re-orient and framing chamber 1100. The framing chamber 1200 includes two substrates 1204a-b, two single substrate frames 1208, and optionally one cross member 1210. Robots mount the substrates 1204a-b onto two single substrate frames 1208 by the process described in reference to FIGS. 11A-C.

Robots (not shown) attach to the two single substrate frames 1208. The robots slide the two single substrate frames 1208 toward the center of the framing chamber 1200. In other embodiments, the robots pickup the two single substrate frames 1208 (e.g., two single substrate frames) in order to move them toward the center of the framing chamber 1200. In certain embodiments, the robots that mount the two substrates 1204a-b onto the substrate frames 1208 are the same as the robots used to slide the substrate frames 1208 toward the center of the framing chamber 1200. Once the robots position the two single substrate frames 1208 in the center of the framing chamber 1200, the cross member 1210 may optionally be used to connect the two single substrate frames 1208 together. The optional cross member 1210 connects to each of the two single substrate frames 1208 with clips. In other embodiments, the cross member 1210 is welded to both single substrate frames 1208 and can expand and contract in order to allow mounting of the substrates 1204a-b onto the single substrate frames 1208. In some embodiments, the single substrate frames 1208 are mounted onto part or all of the walls of the framing chamber 1200. Once substrates are loaded onto the frames 1208, the walls of the framing chamber 1200 move inward to position the two single substrate frames 1208 about 10 cm to about 15 cm apart, more preferably about 11 cm to about 13 cm apart. The frames 1208 are then lowered and mounted onto the cross member 1210 with clips. In certain embodiments, the cross member 1210 includes a vertical portion (shown below with reference to FIGS. 13C-D) at each end that physically supports the frames 1208 and connects to the frames 1208. In some embodiments, the vertical portions of the cross member 1210 attach to the frames 1208 with bearings, such as hinges. The hinges allow the single substrate frames 1208 to rotate around a horizontal axis to better facilitate mounting of substrates 1204a-b onto the single substrate frames 1208. In some embodiments, the single substrate frames 1208 rotate into a horizontal position for loading of the substrates 1204a-b onto the frames 1208. Substrates located in a load lock in a horizontal position slide onto the vertical frames 1208 and the frames 1208 then rotate back into a vertical position for processing of the substrates 1204a-b. The frames 1208 may move through a processing system such as the system 900 separately or in connected pairs.

In some embodiments, the robots connect to the one or more single substrate frames 1208 with mechanical grips. The single substrate frames 1208 are fabricated in order to allow a robot to grip part of the single substrate frame 1208 and move the frame to a different position in the framing chamber 1200. In other embodiments, the robots attach to the single substrate frames 1208 with vacuum suction. In certain embodiments, four single substrate frames 1208 may optionally be connected with three cross members 1210 to form a quadruple substrate frame. The quadruple substrate frame moves throughout the process system (e.g., the process system 900) for processing of the four substrates. The cross members 1210 have interweaving fingers that allow two cross members 1210 to attach to a single substrate frame 1208. The four substrates can be in a face-to-face configuration, such that the two left most substrates are face-to-face, and the two right most substrates are face-to-face, with the middle two substrates would be in a back to back configuration. Alternatively, all four substrates can be back-to-back, such that the four single substrate frames 1208 form a square. In other embodiments, the four single substrate frames form a square and the substrates are in a face-to-face configuration.

FIG. 12B is a perspective view of the framing chamber 1200 with two single substrate frames 1208 optionally connected together with a cross member 1210 to form a dual substrate frame 1212. It is contemplated that the frames 1208 may also move through a processing system such as the system 900 independently or as connected pairs. The substrate frames 1208 are located on top of two rollers 1214a-b. The two rollers 1214a-b help move the substrate frames 1208 out of the framing chamber 1200 and into a transfer chamber (not shown). In some embodiments, the framing chamber 1200 includes one or more upper rollers (not shown) that assist in moving and stabilizing the substrate frames 1208. In other embodiments, one or more conveyors move the substrate frames 1208 into the transfer chamber. Robots (not shown) may be used to move two single substrate frames 1208 supporting substrates 1204a-b into the center of the framing chamber 1200 to allow the optional cross member 1210 to attach to the two frames and form the dual substrate frame 1212. The robots place the substrate frames 1208 onto the rollers 1214a-b such that movement of the rollers 1214a-b moves the substrate frames 1208 out of the framing chamber 1200.

In other embodiments, robots (not shown) load the substrates 1204a-b onto empty substrate frames 1208 positioned on the rollers 1214a-b. Once the robots (such as the robots 1008a-b described with reference to FIG. 10B) mount the substrates 1204a-b onto the substrate frames 1208, the rollers 1214a-b rotate around a horizontal axis running through the middle of the roller and move the substrate frames 1208 into the transfer chamber.

FIG. 12C is a perspective view of the framing chamber 1200 with the two substrate frames 1208 and the two rollers 1214a-b. The substrate frames 1208 may optionally be coupled together to form the dual substrate frame 1212. In some embodiments, the framing chamber 1200 is the same chamber as the framing chamber 906 shown in FIG. 9. The two rollers 1214a-b move the substrate frames 1208 from the framing chamber 1200 to a transfer chamber. The transfer chamber includes two bottom rollers 1216a-b and four top rollers 1218a-b. The bottom rollers 1216a-b contact the bottom surfaces of the substrate frames 1208 (i.e., a dual substrate frame 1212 when the cross member 1210 is used) when the substrate frames 1208 move into the transfer chamber. Each of the top rollers 1218a-b have a “V” shaped groove that touches the top edge of the substrates 1204a-b held in the substrate frames 1208. Contact between the top rollers 1218a-b and the substrates 1204a-b prevents the substrate frames 1208 from tilting and maintains the substrate frames 1208 in a vertical position. In other embodiments, the surface of the top rollers 1218a-b support a flat surface on the upper portion of the single substrate frame 1208 in order to keep the substrate frames 1208 upright. In some embodiments, the bottom rollers are conveyors designed to help move the substrate frames 1208 from the framing chamber 1200 into the transfer chamber. In other embodiments, the top rollers 1218a-b are conveyor belts used to move the substrate frames 1208 from the re-orient and framing chamber 1200. A top or bottom conveyor can be used with either rollers or a conveyor. In some embodiments, the four top rollers 1218a-b are two top rollers such that each roller supports both of the substrates 1204a-b at the same time.

The rollers 1214a-b are motorized and move the pair of substrate frames 1208 out of the framing chamber 1200 into the transfer chamber. In some embodiments, the rollers 1214a-b are not motorized and one or more top rollers (not shown) in the framing chamber 1200 move the substrate frames 1208 into the transfer chamber. In other embodiments, one or more robots (not shown) slide the substrate frame along the rollers 1214a-b and into the transfer chamber. The bottom rollers 1216a-b are motorized and help move the pair of substrate frames 1208 from the framing chamber 1200 into the transfer chamber. The bottom rollers 1216a-b move the substrate frames 1208 into and out of process chambers (e.g., the process chambers 808-832) connected to the transfer chamber. In other embodiments, the bottom rollers 1216a-b are passive (e.g., not motorized) and the top rollers 1218a-b are motorized and move the substrate frames 1208 through the transfer chamber. In certain embodiments, both the bottom rollers 1216a-b and the top rollers 1218a-b are motorized in order to move and stabilize the substrate frames 1208.

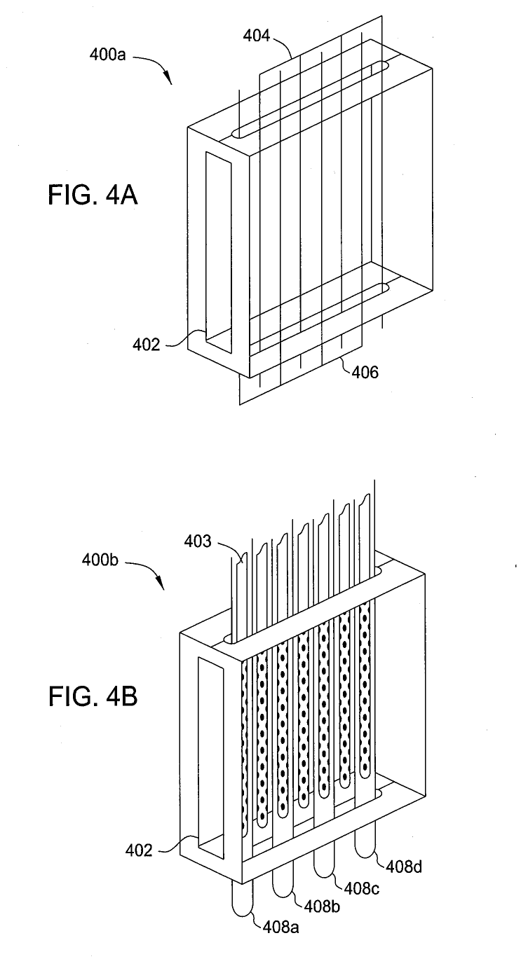

FIG. 4A is a cross section view a process chamber 400a. The process chamber 400a is the same as the process chamber 908. The process chamber 400a may be a plasma enhanced chemical vapor deposition (PECVD), an inductively coupled plasma (ICP) etch chamber, a low pressure chemical vapor deposition chamber (LPCVD), or a hot wire chemical vapor deposition chamber (HWCVD). The process chamber 400a can be used to deposit intrinsic silicon, p-doped silicon, and n-doped silicon films on glass substrates during formation of solar cells, to deposit thin films during manufacturing of flat panel displays, or to etch flat panel displays, 200 mm wafers, or 300 mm wafers held vertically in the process chamber 400a.

The process chamber 400a includes an opening 402 and an antenna structure comprising an upper antenna 404 and a lower antenna 406. The opening 402 allows substrates to move in and out of the process chamber 400a and may be sealed by a door during processing of substrates. In some embodiments, a slit valve is used as a door to create vacuum pressure in the process chamber 400a. In other embodiments, a slide valve closes the opening in the process chamber 400a. The process chamber 400a is reduced to a pressure in the range of about 50 mTorr to about 150 mTorr during processing.

The antenna structure is centrally located within the process chamber 400a. The upper antenna 404 and the lower antenna 406 create inductively coupled or capacitively coupled plasma for deposition of layers onto two substrates (not shown), such as a pair of substrates positioned in the processing chamber. Power may be supplied to the antenna structure to generate a varying electric field at frequencies between about 300 kHz and about 3 GHz. In one embodiment, RF power source is provided at a frequency of 13.56 MHz. In other embodiments, HF or VHF power may be provided. In still other embodiments microwave frequency (MF) power may be provided at frequencies between about 600 MHz and about 3 GHz, for example about 900 MHz or about 2.45 GHz. In some embodiments, frames holding the substrates (e.g., the single or dual substrate frame 918, or any of the frames described below in connection with FIGS. 13A-13I) provide DC bias to the substrates in order to reduce substrate damage. The DC bias power applied to the substrate frames comes from a different power supply than the source power supplied to the antennas 404 and 406. In other embodiments, the substrates are not biased by the substrate frames. The antennas 404 and 406 use different source power supplies in order to generate plasma. In other embodiments, the antennas 404 and 406 use the same source power supply. The antennas 404 and 406 provide power which ignites and sustains plasma in the process chamber 400a for deposition onto two glass substrates. The temperature of the process chamber 400a during deposition is between about 20° C. (i.e., room temperature) and about 400° C., for example about 130° C.

The antennas 404 and 406 may be manufactured from aluminum or quartz. The antennas 404 and 406 are formed in the shape of a cylindrical coil with a hollow core to allow process gas to flow through the antennas 404 and 406. In some embodiments, the antennas 404 and 406 are straight wire conductors without a core. In other embodiments, the antennas 404 and 406 are straight wire conductors molded with a hollow core to allow process gas to flow through the hollow core. The upper antenna 404 and the lower antenna 406 have a longest uninterrupted dimension of about 3 m or less in order to reduce arcing during deposition. Longer antenna dimensions not connected to either a source or a ground have increased resistance and require increased voltage to allow current to pass through the antenna. The increased voltage at the ends of the antenna increases the chance of arcing. In some embodiments, the antennas 404 and 406 have multiple feed points for source power in order to reduce the longest uninterrupted dimension and the likelihood of arcing. Both the upper antenna 404 and the lower antenna 406 have a comb shape with four blades extending into the process chamber 400a. In some embodiments, the upper antenna 404 and the lower antenna 406 have a different number of blades. In certain embodiments, the upper antenna 404 and the lower antenna 406 have from about 2 to about 8 blades. A ceramic tube (discussed with reference to FIGS. 12A-D) may surround each of the antennas 404 and 406 to prevent films from depositing onto the antennas 404 and 406. The ceramic tubes may include holes for introduction of process gases into the process chamber 400a. The ceramic tubes may further include electrodes in order to reduce deposition of the process gases on the tubes and to create sputtering so that the tubes are self cleaning. In some embodiments, the electrodes in the ceramic tubes create a capacitive coupling in order to sputter off films deposited on the ceramic tubes.

Substrates are held in a face-to-face configuration in the process chamber 400a by a pair of substrate frames. The antenna structure comprising the upper antenna 404 and the lower antenna 406 is positioned between the two face-to-face substrates as shown in FIGS. 13A-I below. Gas is introduced into the process chamber 400a between the two substrates. The gas may be provided from the ceramic tubes, as described above, or through a gas feed structure comprising gas feed tubes interspersed among the blades of the antennas 406 and 408, as is further described below in connection with FIG. 4B. The antennas 404 and 406 ignite a plasma in the process chamber 400a. The antennas 404 and 406 are located in the process chamber 400a such that they form a uniform ion density and substantially planar films are deposited on the two substrates.

Face-to-face orientation of the two substrates allows ignition of only one plasma field in the process chamber 400a instead of two separate plasma fields for two substrates in separate process chambers or in separate processing regions. The use of only one plasma field requires less gas to form the plasma and reduces the consumption and waste of gases. The upper antenna 404 and the lower antenna 406 use less energy to create a plasma in the process chamber 400a than needed to create two plasma fields for processing two substrates separately. Cleaning time and gases are reduced because one chamber is cleaned instead of two. In some single substrate processing environments the percent of the process chamber exposed to a plasma formed in the process chamber is high. In the dual substrate processing chamber 400a the percent of the chamber walls exposed to the plasma is low, as will be discussed in greater details with reference to FIGS. 13A-I below. The reduction in the amount of the chamber exposed to the plasma also helps reduce cleaning times. Processing two substrates in a single process chamber, such as the process chamber 400a, reduces overhead cost (e.g., the cost of the chamber) and saves factory floor space. Moving two substrates in pairs of substrate frames, such as the substrate frames 916 or the dual substrate frame 918, increase substrate throughput.

In some embodiments, the process chamber 400a is divided into two tandem processing chambers. A wall (not shown) can optionally be placed in the middle of the chamber such that the antennas 404 and 406 are located in the wall. Process gases can be introduced into the two tandem chambers from the wall. The opening 402 may be divided into two openings in such an embodiment, one for each of the process chambers. Individual substrate frames, such as the single substrate frames 916, move substrates into and out of the process chamber 400a. The tandem process chambers have separate exhaust pumps. In some embodiments, the tandem process chambers share the same exhaust pump.

FIG. 4B shows a cut out view of a process chamber 400b. The process chamber 400b is another embodiment of the process chamber 908 for processing two substrates held substantially vertically in two substrate frames. The process chamber 400b includes the opening 402 and an antenna structure comprising four U-shaped antennas 408a-d. In a preferred embodiment, the U-shaped antennas 408a-d are manufactured from aluminum and are surrounded by ceramic tubes. In some embodiments, the ceramic tubes are made from aluminum oxide. In other embodiments, the ceramic tubes are made from carbide.

The U-shaped antennas 408a-d are positioned in the process chamber 400b such that they form a uniform ion density in the process chamber 400b and substantially planar films are deposited on the two substrates held on either side of the antennas 408a-d. In other embodiments, between about three and about eight U-shaped antennas are located in the process chamber 400b. In some embodiments, the U-shaped antennas 408a-d are flipped along a horizontal axis such that the bottom of the “U” is above the process chamber 400b. In certain embodiments, the process chamber 400b processes eight substrates at a time, four on either side of the U-shaped antennas 408a-d. In such an embodiment, each single substrate frame in the dual substrate frame is configured to hold four substrates in a substantially coplanar configuration for a total of eight substrates.

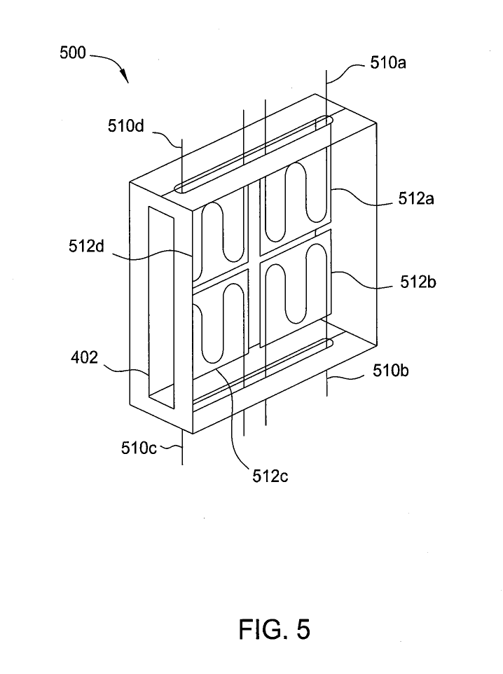

Gas may be fed to the process chamber 400b through the ceramic tubes surrounding the antennas 408a-d, as described above in connection with FIG. 4A, or through a gas feed structure comprising gas feed tubes 403 that enter the process chamber 400b through the top or bottom thereof. The gas feed tubes 403 are interspersed among the antennas 408a-d. The gas feed tubes 403 may be oriented along two planes, each plane between the antenna structure and one substrate frame. The gas feed tubes 403 comprise openings distributed along a length thereof for dispensing process gases into the reaction space between the substrate frames. The openings of the gas feed tubes 403 are spaced and oriented to provide a uniform gas flow throughout the reaction zone. The gas feed tubes 403 may be formed from any convenient material for processing chambers, such as aluminum, quartz, stainless steel, ceramic (such as alumina), and the like. It should be noted that the gas feed tubes 403 are shown only in the embodiment of FIG. 4B to enhance clarity of the figures, and may be used in any of the embodiments of FIGS. 4A-B and FIG. 5 or any other embodiment of a vertical or substantially vertical processing chamber.

FIG. 5 is another cut out view of a process chamber 500. The process chamber 500 is another embodiment of the process chamber 908. The process chamber 500 includes the opening 402 and an antenna structure comprising four antennas 510a-d. Four substrates 512a-d are shown positioned in the process chamber 500 to illustrate one method of using the process chamber 500. The process chamber 500 may be divided into a total of eight substrate process positions, four on either side of the four antennas 510a-d. The eight substrates are held in a multi-substrate frame. In other embodiments, two substrates held in substrate frames are processed in the process chamber 500, substantially as described above in connection with FIGS. 4A-B and in connection with FIGS. 13A-I below. The shorter antennas 510a-d used in the process chamber 500 reduce the chance of arcing during processing of the substrates 512a-d.

In certain embodiments, the process chamber 500 may be operated to processes four vertically oriented substrates at a time. Substrates frames may be positioned on each side of the process chamber 500 such that each of the four substrates is positioned on a different plane. In such an embodiment, the process chamber 500 may include two sets of antennas 510a-d in two antenna structures in order to create two plasma processing fields in order to deposit films on the four substrates. Gas feed may be provided using a gas feed structure comprising two or four ranks of gas feed tubes such as the gas feed tubes 403 of FIG. 4B. The process chamber 500 typically includes one exhaust system in order to evacuate the process chamber 500 after deposition, but may include two exhaust systems, one for each of the processing regions.

FIG. 13A is a schematic cross-section view 1300a of a dual substrate frame 1302 including two single substrate frames 1304a-b and a cross member 1306a. The dual substrate frame 1302 carries two substrates 1308a-b throughout a process system, such as the process system 900. The bottom surface of the cross member 1306 contacts the horizontal surface of a bottom roller 1310 and the dual substrate frame 1302 is stabilized by two top rollers 1312a-b contacting the top edge of the two substrates 1308a-b. The bottom roller 1310 moves the dual substrate frame 1302 by rotating around horizontal axis that runs through the middle of the bottom roller 1310. A motor (not shown) connected to the bottom roller 1310 provides rotational movement to the bottom roller 1310. In certain embodiments, multiple bottom rollers 1310 help move the dual substrate frame 1302 through a process system.

The dual substrate frame 1302 is stabilized by the support of the top rollers 1312a-b. The top rollers 1312a-b have a “U” shaped groove in the horizontal surface of the top rollers 1312a-b that touches the top edge of the substrates 1308a-b respectively, and keeps the substrates 1308a-b centered horizontally in the “U” shaped groove. Each of the top rollers 1312a-b is not connected to motors and each rotates around a horizontal axis as the substrates 1312a-b move through a process system and the top edges of the substrates 1308a-b make contact with the top rollers 1312a-b. The bottom roller 1310 has the same configuration as the bottom rollers 922, and the top rollers 1312a-b are the same as the top rollers 924. In some embodiments, the bottom roller 1310 and the top rollers 1312a-b are the same as the bottom rollers 926 and the top rollers 928 respectively.

The dual substrate frame 1302 holds the substrates 1308a-b in place with electrostatic charge. Electrodes placed within the dual substrate frame form bipolar electrostatic chucks to hold the substrates 1308a-b against the surface of the dual substrate frame 1302. In certain embodiments, the electrodes in the dual substrate single substrate frames 1304a-b are monopolar such that the charge of the electrode in the single substrate frame 1304a and the charge of the electrode in the single substrate frame 1304b create electrostatic force and hold the substrates 1308a-b in place. In some embodiments, the dual substrate frame 1302 uses vacuum pressure on the backside of the substrates 1308a-b to hold the substrates 1308a-b in place. The dual substrate frame 1302 contains grooves (not shown) on the surface of the frame 1302 directly behind the substrates 1308a-b. A process system (e.g., the process system 900) creates a vacuum in the grooves on the dual substrate frame 1302 in order to hold the substrates 1308a-b in place. In other embodiments, the dual substrate frame 1302 holds the substrates 1308a-b in place by making physical contact with the edges of the substrates 1308a-b. The dual substrate frame 1302 can use clamps (not shown) to make contact with the front edges of the substrates 1308a-b. The size of the edge exclusion zone (the distance that the clamp comes into contact with the front surface of the substrate) is 3 mm or less, preferably 2 mm or less, more preferably 1 mm or less.

The dual substrate frame 1302 has grooves on the surface directly behind the substrates 1308a-b. The grooves allow inert gas, such as helium, to contact the back surface of the substrates 1308a-b in order to cool the substrates 1308a-b during processing. Alternatively, the frame 1302 can have indentations that allow cooling gas to come into contact with the backside of the substrates 1308a-b. In some embodiments, the dual substrate frame 1302 has two sets of grooves on the surface directly behind the substrates 1308a-b: a first set of grooves provides vacuum suction to hold the substrates 1308a-b in place, and a second set of grooves provides backside cooling gas to contact the substrates 1308a-b.

In certain embodiments, the bottom roller 1310 is split into a left and a right roller. Examples of such embodiments are shown in FIGS. 13G and 13H. Reduced contact with the bottom of the dual substrate frame 1302 reduces the chance of particle contamination on the substrates 1308a-b. In other embodiments, the bottom roller 1310 is a conveyor that moves the dual substrate frame 1302 through a process system.

In certain embodiments, the top rollers 1312a-b include “V” shaped grooves to hold the substrates 1308a-b in the center of the top rollers 1312a-b respectively. The top rollers 1312a-b stabilize the dual substrate frame 1302 and prevent it from tipping over by making contact with the substrates 1308a-b which are held firmly in place against the dual substrate frame 1302.

FIG. 13B is another schematic cross-sectional view 1300b of the dual substrate frame 1302. Two side rollers 1314a-b contact an upper portion of the dual substrate frame 1302. Each of the side rollers 1314a-b rotates around a vertical axis when the side rollers 1314a-b contact the dual substrate frame 1302. The vertical surface of the side rollers 1314a-b supports the dual substrate frame 1302 and prevents the dual substrate frame from tilting while the dual substrate frame 1302 is moved through a process system. In some embodiments, each of the side rollers 1310a-b is a conveyor that guides the dual substrate frame 1302 along on the bottom roller 1310. Each of the side rollers 1314a-b is bolted to the top of the processing system. In some embodiments, each of the side rollers 1314a-b is attached to the bottom of the processing system. Side rollers attached to the bottom of the process system allow transfer chambers, such as transfer chamber 904, to have only one turntable 920 and reduces the number of moving parts.

In certain embodiments, the bottom roller 1310 includes two grooves 1316 that guide two protrusions 1318 that are mounted onto the bottom of the dual substrate frame 1302. The two protrusions 1318 extend vertically into “U” shaped opening of the two grooves 1316 located on the bottom roller 1310. Each of the grooves 1316 center the respective protrusion 1318 in the “U” shaped opening. Centering of the protrusions 1318 in the grooves 1316 keeps the dual substrate frame 1302 centered on the bottom roller 1310 during movement of the dual substrate frame 1302. In other embodiments, the bottom roller 1310 has a single groove in the center of the bottom roller 1310 and the dual substrate frame 1302 has a single protrusion. The single protrusion extends into the single groove and centers the dual substrate frame 1302 on top of the bottom roller 1310 and reduces possible contaminate sources.

FIG. 13C is another schematic cross-sectional view 1300c of the dual substrate frame 1302 holding the substrates 1308a-b. A bottom roller pair 1320a-b moves the dual substrate frame 1302 throughout a processing system, such as the processing system 900. The bottom roller pair 1320a-b includes a pair of grooves 1322a-b that center the dual substrate frame 1302 above the bottom roller pair 1320a-b. Two protrusions 1324a-b mounted on the bottom of cross member 1306b extend vertically into the “U” shaped openings of the grooves 1322a-b. The grooves 1322a-b contact the edges of the protrusions 1324a-b and center each of the individual protrusions 1324a-b in the corresponding groove 1322a-b keeping the dual substrate frame 1302 centered above the bottom roller pair 1320a-b. In some embodiments, the grooves 1322a-b have “V” shaped openings that contact the protrusions 1324a-b. In certain embodiments, the protrusions 1324a-b have a “U” shape designed to fill the corresponding “U” shape of the grooves 1322a-b.

The dual substrate frame 1302 includes two edges 1330 to support the bottom edge of the substrates 1308a-b. The edges 1330 allow the cross member 1306b of the dual substrate frame 1302 to have two vertical side pieces that physically connect to the single substrate frames 1304a-b. Extending the cross member 1306b of the dual substrate frame 1302 down from the substrates 1304a-b reduces the amount of material deposited on the cross member 1306b during processing of the substrates 1308a-b. In some embodiments, process chambers (e.g., the process chambers 908) include masks that further reduce contamination on the cross member 1306b. In certain embodiments, an inert gas flow across the cross member 1306b further reduces particle contamination.

FIG. 13D is a cross sectional view 1300d of the substrates 1308a-b mounted onto two electrostatic chucks 1304c-d. Each of the electrostatic chucks 1304c-d includes two electrodes for bipolar electrostatic operation. Each of the electrostatic chucks 1304c-d includes four lower fingers 1332 and four upper fingers 1378. The electrostatic chucks 1304c-d hold the substrates 1308 onto the dual substrate frame 1302 and the upper and lower fingers 1378 and 1332 help hold the substrates 1308 in place and prevent the substrates 1308 from sliding. In some embodiments, each of the electrostatic chucks 1304c-d includes eight side fingers to hold the left and right sides of the substrate. In certain embodiments, the electrostatic chucks 1304c-d include side fingers on one side of the substrate.

When the electrostatic chucks 1304c-d hold the substrates 1308, the substrates 1308 rest upon the lower fingers 1332 and there is space between the substrates 1308 and the upper fingers 1378. During loading and unloading of the substrates 1308 onto and off of the electrostatic chucks 1304c-d, fingers on the framing robot (not shown) interleave with the fingers 1332 and 1378 attached to the electrostatic chucks 1304c-d. The framing robot fingers hold the substrates 1308 about 1 mm to about 10 mm above the lower fingers 1332 to prevent damage to the substrates 1308, preferably about 2 mm. In other embodiments, the framing robot fingers hold the substrates 1308 less than 1 mm above the lower fingers 1332. The upper and lower fingers 1378 and 1332 are square and have a width of from about 5 mm to about 10 mm such that minimal deposition onto the fingers 1378 and 1332 occurs during processing of the substrates 1308.

In some embodiments, the electrostatic chucks 1304c-d are vacuum chucks. In other embodiments, the electrostatic chucks 1304c-d use directional adhesive to hold the substrates 1308a-b in place without contaminating the substrates 1308a-b.

FIG. 13E is a schematic cross-sectional view 1300e of a process chamber 1301 with a dual substrate frame 1302 sitting in the process chamber 1301. The process chamber 1301 includes a pair of rollers 1320, a mask 1376, a cross member 1306b, and an antenna 1374. The dual substrate frame 1302 holds a pair of substrates 1308. The pair of rollers 1320 moves the dual substrate frame 1302 into and out of the process chamber 1301. Each of the rollers 1320 includes a “U” shaped groove 1322 and the cross member 1306b of the dual substrate frame 1302 includes a pair of protrusions 1324. The protrusions 1324 extend vertically into the “U” shaped grooves 1322. The grooves 1322 contact the edges of the protrusions 1324 and center each of the individual protrusions 1324 in the corresponding “U” shaped groove 1322 keeping the dual substrate frame 1302 centered above the pair of rollers 1320 and centered in the process chamber 1301. In some embodiments, the grooves 1322 have “V” shaped openings that contact the protrusions 1324. In certain embodiments, the protrusions 1324 have a “U” shape designed to fill the corresponding “U” shape of the grooves 1322.

The dual substrate frame 1302 includes two edges 1330 to support the bottom edge of the substrates 1308. The mask 1376 reduces particle contamination on the cross member 1306b. The mask 1376 is cantilever mounted onto a side wall of the process chamber 1301. In certain embodiments, an inert gas flow across the cross member 1306b further reduces particle contamination. In some embodiments, additional masks prevent deposition of process gas on the top side and walls of the process chamber 1301.

In some embodiments, each individual frame 1304a-b of the dual substrate frame 1302 holds each substrate 1308a-b in place with vacuum suction. In other embodiments, the substrate frames 1304 use directional adhesive to hold the substrates 1308 in place without contaminating the substrates 1308.

FIG. 13F is another schematic cross-sectional view 1300f of a process chamber 1301 that includes a pair of rollers 1320, a mask 1376, and an antenna 1374. The process chamber 1301 is an embodiment of the process chamber 908. The rollers 1320 support a dual substrate frame 1302 during processing of two substrates 1308. The dual substrate frame 1302 includes a cross member 1306c and two electrostatic chucks 1304. Each of the electrostatic chucks 1304 includes four upper fingers 1378, four lower fingers 1332, and two electrodes for bipolar operation. The upper fingers 1378 and the lower fingers 1332 hold the substrates 1308 in place and prevent the substrates 1308 from sliding. In some embodiments, the electrostatic chucks 1304 include eight side fingers (e.g., four fingers on each side) to further reduce the possibility of the substrates sliding on the electrostatic chucks 1304. The electrostatic chucks 1304 hold the substrates 1308 onto the dual substrate frame 1302.

The dual substrate frame 1302 includes a cross member 1306c, that with the pair of rollers 1320 move the dual substrate frame 1302 into and out of the process chamber 1301. Each of the rollers 1320 include “U” shaped grooves 1322 and the cross member 1306c of the dual substrate frame 1302 includes a pair of protrusions 1324. The protrusions 1324 extend vertically into the “U” shaped grooves 1322. The grooves 1322 contact the edges of the protrusions 1324 and center each of the individual protrusions 1324 in the corresponding “U” shaped groove 1322 keeping the dual substrate frame 1302 centered above the pair of rollers 1320 and centered in the process chamber 1301. In some embodiments, the grooves 1322 have “V” shaped openings that contact the protrusions 1324. In certain embodiments, the protrusions 1324 have a “U” shape designed to fill the corresponding “U” shape of the grooves 1322.

FIG. 13G is another schematic cross-sectional view 1300g of a dual substrate frame 1302. The dual substrate frame 1302 of FIG. 13G is substantially similar to the dual substrate frame 1302 of FIG. 13A, with the cross member 1306a replaced by dual cross members 1306e-f, and the roller 1310 replaced by dual rollers 1310c-d, which together with the dual cross members 1306e-f define an opening 1340 between the frames 1304a-b of the dual substrate frame 1302. The opening 1340 extends substantially the full length of the dual substrate frame 1302 and allows access to the reaction space between the substrates 1308 from the chamber bottom. Each of the dual rollers 1310c-d may be motorized individually, or the dual rollers 1310c-d may be joined by an optional axle 1341, which may be driven by a common motor. Alternately, the dual rollers 1310c-d may be passive, non-motorized members.

FIG. 13H is another schematic cross-sectional view 1300j of a dual substrate frame 1302. The dual substrate frame 1302 of FIG. 13G is substantially similar to the dual substrate frame 1302 of FIG. 13B, with the cross members 1306e-f and the dual rollers 1310c-d with the optional axle 1341. The antenna structure comprising the upper and lower antennas 404 and 406 of FIG. 4A is shown juxtaposed with the dual substrate frame 1302 in FIG. 13H to illustrate access to the reaction zone between the two substrates 1308 through the chamber bottom facilitated by the opening 1340.

FIG. 13I is another schematic cross-sectional view 1300i of a process chamber 1301 according to another embodiment. The process chamber 1301 features upper and lower conveyors 1346 and 1344, respectively, for substrate frames 1342 disposed on each substantially vertical wall 1372 of the process chamber 1301. The conveyors 1344 and 1346 may be rollers or slides that engage the substrate frames 1342 at recesses 1350 and 1364 in respective frame extensions 1348 and 1360. Protrusions 1362 in the conveyors 1344 and 1346 engage the recesses 1350 and 1364 to control positioning and motion of the substrate frames 1342 in the process chamber 1301. The protrusions 1362 may be wheels in embodiments featuring rollers. The extensions 1348 and 1360 may be rails with grooves for engaging rollers. Substrates 1308 may be adhered to the substrate frames 1342 in any of the ways aforementioned, such as electrostatic, vacuum, of chemical adhesion, or by physical gripping if fingers are included on the substrate frames 1342. Each of the lower conveyors 1344 may be a dual roller with the two rollers of each dual roller disposed on either side of a central plane of the substrate carrier 1342. The rollers thus positioned provide stability to the substrate carrier 1342, tending to keep the substrate carrier 1342 in an upright position. It will also be noted that the lower conveyors 1344 may be lowered into the floor of the processing chamber 1301 such that only the wheels 1362 protrude above the floor of the processing chamber 1301.

An antenna structure 1352 extends linearly through the process chamber 1301. The antenna structure 1352 may be centrally located inside the process chamber 1301 to form a reaction zone between the two substrates 1308. The antenna structure 1352 comprises one or more antennas, each of which comprises a conductor 1370 surrounded by an insulating sleeve 1368. The antenna structure 1352 may include a plurality of antennas disposed in a linear array. The conductor 1370 may be a solid metal rod or metal tube. The conductor 1370 is coupled to a source of electric power 1354, which may be an RF, HF, VHF, or MF source as shown in FIG. 13I. The insulating sleeve 1368 prevents deposition of reaction products on the conductor 1370. The antenna structure 1352 is shown entering the process chamber 1301 through the top, but antennas may enter through the bottom instead of, or in addition to, the top, as in any of the embodiments of FIGS. 4A-C. The antenna structure 1352 of FIG. 13I is oriented along a plane through a central location of the process chamber 1301 substantially coplanar with the planes defined by substrates 1308 housed in the process chamber 1301. The antenna structure 1352 is shown protruding through the top of the process chamber 1301, but alternate embodiments are contemplated in which the antenna structure 1352 protrudes through the bottom of the chamber 1301, or through both the top and bottom of the chamber 1301.

Gas feed tubes 1356 are positioned between the antenna structure 1352 and the substrates 1308. The gas feed tubes 1356 are oriented along planes either side of the antenna structure 1352, and substantially coplanar therewith. The gas feed tubes 1356 are spaced with respect to the antenna structure 1352 and the substrates 1308 to provide uniform reactant density throughout the reaction space between the substrates 1308. Holed 1358 in the gas feed tubes 1356 are positioned and spaced to provide uniform flow of gases into the reaction space according to a distribution pattern 1366.

FIG. 13J is a top view of the process chamber 1301 of FIG. 13H. The chamber wall 1372 and the positioners 1346 position the substrate frames 1342 holding the substrates 1308 in a position exposed to the reaction space between the substrates 1308. The pattern of antennas 1352 and gas feed tubes 1356 exemplified is one embodiment that may provide uniform processing of the substrates 1308. The gas feed tubes 1356 are interspersed among the antennas 1352, and positioned between the antennas 1352 and the substrates 1356. The distribution pattern 1366 of the holes 1358 in the gas feed tubes 1356 is generally selected for uniform gas input to the process chamber 1301.

It will be understood from the description above that the gas feed tubes need not be straight vertical tubes in all embodiments. Virtually any configuration of feed tubes traversing the space between the antenna structure and the substrates may be used.

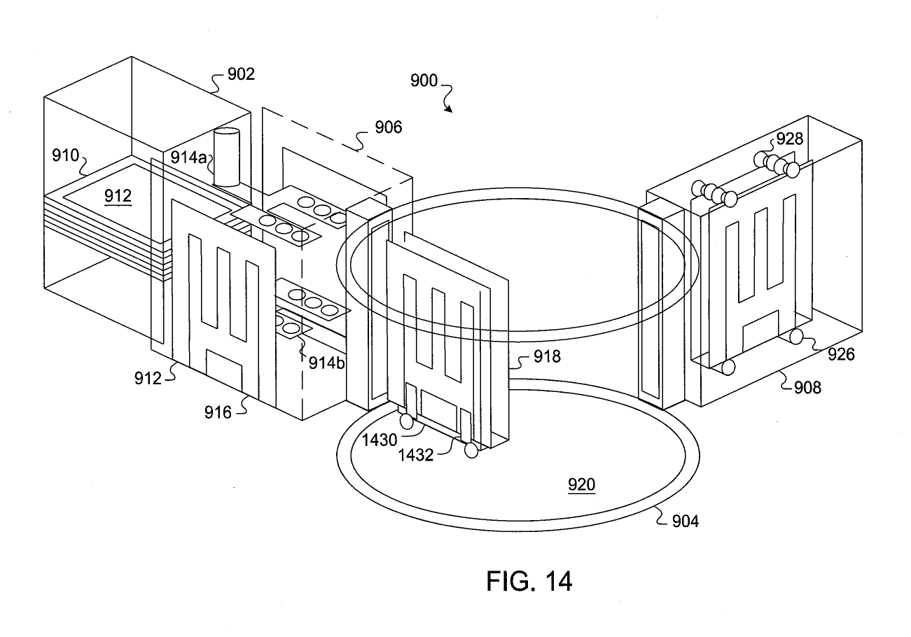

FIG. 14 is a perspective view of the process system 900 with a frame transport shuttle 1430. The frame transport shuttle 1430 supports the dual substrate frame 918 during movement of the dual substrate frame 918 through the process system 900. The frame transport shuttle 1430 includes four plates 1432 that attach to the dual substrate frame 918 hold the frame 918 securely in place during movement. In some embodiments, the process system 900 includes one frame transport shuttle 1430 for each of the processing chambers 908. In other embodiments, there is more than one frame transport shuttle 1430 for each of the processing chambers 908 (e.g., if there are 13 processing chambers 908, the system 900 includes 17 frame transport shuttles 1430).

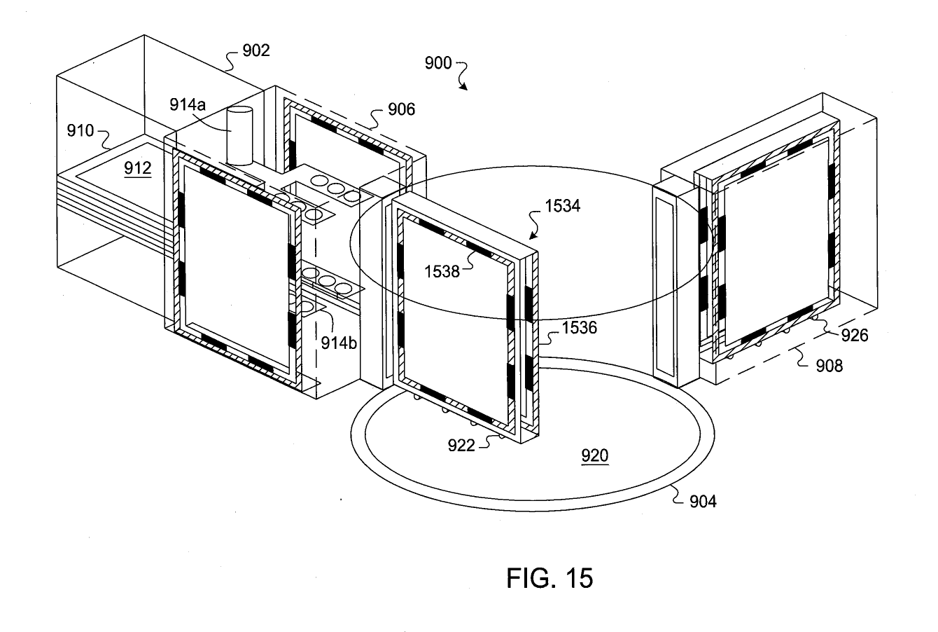

FIG. 15 is another perspective view of the process system 900 with a substrate frame 1534 used to move a pair of substrates within a processing system such as the system 900. The substrate frame 1534 includes a guide rail 1536 and sixteen substrate fingers 1538 attached to the guide rail 1536 with bearings. Eight substrate fingers 1538 connect to each of the substrates 912 mounted onto the substrate frame 1534. The bearings that attached the substrate fingers 1538 and the guide rail 1536 allow movement of the fingers and allow the substrate 912 to warp without cracking during processing. The substrate fingers 1538 attach mechanically to the substrates 912 by contacting the edge and backside of the substrates 912 and a minimal amount of the front surface of the substrates 912. The substrate fingers 1528 preferably contact the substrate 912 front side 3 mm or less, preferably 2 mm or less, more preferably 1 mm or less.

FIG. 16A is a three-dimensional view of a load lock/cooling cassette shown in cross-section in FIG. 16B. A heating/cooling cassette 10 comprises sidewalls 12 and 14 and a bottom wall 16. A lid 18 is fastened to the top of the cassette 10. Additional side walls 13 and 15, shown in FIG. 16A, are perpendicular to sidewalls 12 and 14. Sidewall 13, adjacent to the system 40, is fitted with a slit valve 11 through which the glass plates can be transferred into and out of the cassette 10. The system 40 may be any of the systems 600, 700, 800, or 900, or another system. In certain embodiments, there can be two slit valves 11, one for transferring substrates into a central robotic chamber 50 and one for transferring substrates out of the central robotic chamber 50. In some embodiments, the heating/cooling cassette 10 contains two separate cassettes or chambers. The upper chamber pre-heats substrates before processing and attaches to a slit valve that allows the substrates to move into the central robotic chamber 50. The lower chamber cools substrates after processing and attaches to a slit valve that allows substrates to be placed into the cooling chamber from the central robotic chamber 50. The heating/cooling cassette 10 and/or any cassettes/chambers contained in the heating/cooling cassette 10 hold one or more substrates. The cassettes can be used for batch processes (e.g., holding two or more substrates) or for single substrate processing. The central robotic chamber 50 may be any of the transfer chambers 602, 704, 804, or 904.

The sidewalls 12 and 14 are fitted with electric resistor heating coils 20 and with cooling channels 22 in which a cooling gas or liquid can be circulated. For example, a cooling gas such as helium or a liquid such as water can be controllably circulated in the channels 22 by means of a suitable pump (not shown).

The bottom wall 16 is fitted with inlet and outlet pipes 24 and 26 respectively for circulation of coolant and/or a channel 27 for containing wires for heating coils 20 which are connected to a source of power (not shown). Alternatively, the same channels 24, 26 can be used both for enclosing the heating coils 20 and for circulating the cooling gas or liquid in the channels 22.

The interior of the sidewalls 12 and 14 are fitted with a plurality of heat conductive shelves 28. The shelves 28 must make good contact with the walls 12 and 14 to ensure rapid and uniform control of the temperature of the shelves 28, depending on whether the walls 12 and 14 are being heated or cooled. The shelves 28 are made of a good heat conductor, such as metal including aluminum, copper, stainless steel clad copper, and the like.

Situated on the shelves 28, or fastened thereto, are a plurality of supports 30 that are suitably made of a non-conductive material such as high temperature glass or quartz. The supports 30 serve to support the glass substrates 32 to be processed so that there is a gap between the shelves 28 and the substrates 32. This gap ensures that direct contact of the shelves to the glass is avoided which might stress and crack the glass. The glass is heated and cooled indirectly by radiation and gas conduction rather than by direct contact of the substrates 32 and the shelves 28. Further, the interleaving of the glass substrates 32 and the shelves 28 provides heating and cooling of the glass substrates 32 from both sides, providing more rapid and more uniform heating and cooling of the substrates.

The temperature of the conductive shelves 28 can be regulated by the heating coils or cooling media in the channels 20, 22 within the sidewalls 12 and 14, to which walls the conductive shelves 28 are contacted or affixed. The conductive shelves 28 must contact the walls 12 and 14 in both the heating and cooling arrangement. The rate of heating or cooling glass substrates is determined by the emissivity of the shelf material, the emissivity of the glass itself and the vacuum pressure of the chamber and can be slow enough so that cracking of the glass is avoided. The heat transport described by the Stephan-Boltzmann equation is given in equation 1) below:
a.

$${E}_{r} = \frac{σ {\sum }_{1} {\sum }_{2}}{{\sum }_{1} + {\sum }_{2} - {\sum }_{1} {\sum }_{2}} ( {T}_{1}^{4} - {T}_{2}^{4} ) \qquad 1 )$$

b. where Eᵣ is the amount of energy transported in Watts/cm²;
c. T₁ is the temperature of the shelves in Kₒ;
d. T₂ is the temperature of the glass in Kₒ;
e. □₁ is the emissivity of the shelves;
f. M₂ is the emissivity of the glass; and
g. is the Stefan-Boltzmann constant and heat transfer by gas conduction is proportional to the gas pressure and is given by equation 2) below:
h.

$${E}_{c} = \frac{Δ ( {T}_{1} - {T}_{2} ) B}{d + 2 Bc} * P \qquad 2 )$$

i. where E_{c} is the heating energy in Watts/cm²;
   i. is the mean conductivity in Kₒ;
j. d is the gap between planes in cm;
   1. is the gas accommodation coefficient;
k. c is the gas mean free path in microns;
l. p is the pressure in millitorr; and
m. T₁ and T₂ have the meanings given above for equation 1)

The number of substrates in the batch must be adjusted to provide an economic process. By heating and cooling the glass substrates 32 in a batch-type step, more time is available for heating and cooling of each individual substrate, thus preventing warping or cracking of the glass.

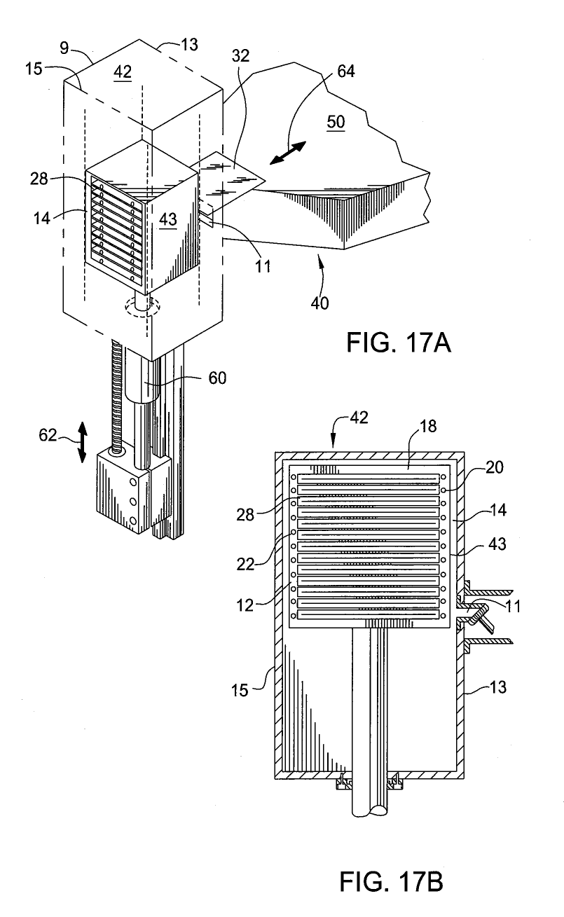

The operation of any of the systems 600, 700, 800, or 900, in which the present heating/cooling chambers are used, is shown in FIG. 17. The central robotic chamber 50 contains a robot (not shown) that can transfer the glass substrates 32 from the heating/cooling cassette 10 through a suitable opening or slit valve 11 in the sidewall 13 adjacent to the chamber 50. The chamber 50 may be any of the transfer chambers 602, 704, 804, or 904. When the glass substrates have reached CVD processing temperature the robot transfers a single substrate 32 to one of the processing chambers 52, 54, 56 or 58 for deposition of a thin film thereon. The robot can also transfer a glass substrate 32 from one of the processing chambers 52, 54, 56 and 58 to another in any predetermined sequence as shown by the arrows 51. After processing is complete, the robot transfers the glass substrate 32 back to the cassette 10 for cooling down to ambient temperatures. Thus a batch of glass substrates 32 are heated up to processing temperature in the cassette 10, various thin films are deposited onto the glass substrates 32 one at a time in the CVD processing chambers, and then a batch of substrates is cooled back to ambient temperature. A slit valve 59 in the sidewall 15 of the chamber 9 allows loading and unloading of the glass substrates 32 into the system 40. In some embodiments, the slit valve 59 is two slit valves, one for loading glass substrates 32 into a heating chamber in the cassette 10 and one for unloading glass substrates from a cooling chamber in the cassette 10. In certain embodiments, the heating/cooling cassette 10 has multiple heating chambers and multiple cooling chambers. The cassette 10 can have two heating chambers, one for transferring heated glass substrates 32 into the processing chambers 52, 54, 56 and 58, and one for loading glass substrates 32 into the cassette 10.

Although the above description of the processing chambers are directed to CVD chambers, other processing chambers can be added or substituted in the vacuum system 40, such as physical vapor deposition chambers, etch chambers, anneal chambers, preclean chambers and the like.

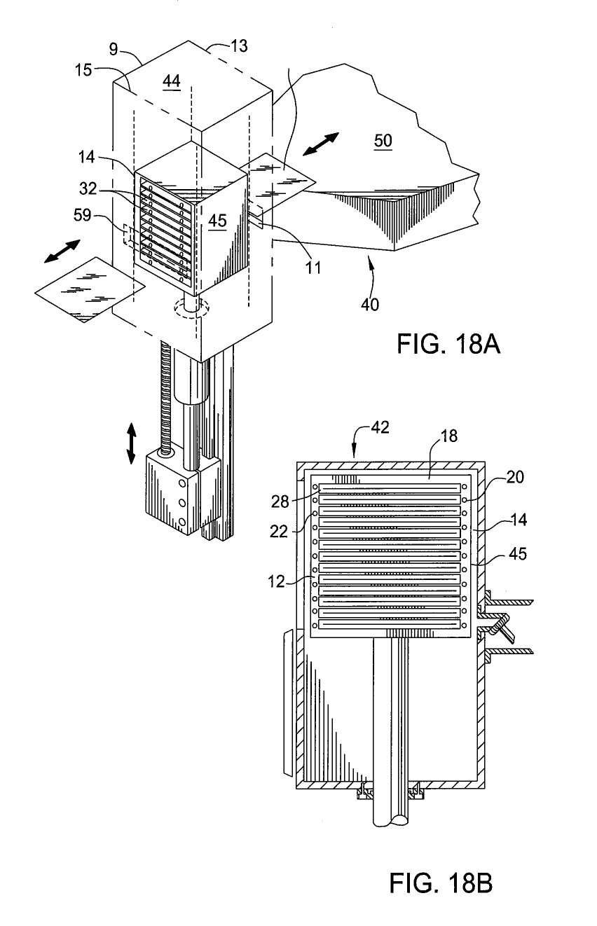

Alternatively, separated or integrated heating and cooling chambers 42 and 44 may be provided in the system 40. FIG. 18B is a cross sectional view of a heating chamber 42 and heating cassette 43 and FIG. 18A is a three dimensional view of the heating chamber 42. The heating chamber 42 includes a heating cassette 43 which contains only resistance heating coils in the sidewalls 12 and 14, and a single slit valve 11 in sidewall 13 connects to a robotic chamber 50, which may be a transfer chamber such as the transfer chamber 602 of FIG. 6.

FIGS. 18A and 18B are a three dimensional view and a cross sectional view, respectively, of a cooling/load lock chamber 44 and cooling cassette 45. The cooling cassette 45 contains only channels for a coolant to be circulated in the sidewalls 12 and x14. The cooling cassette 45 can, for example, double as a load lock chamber and thus each of the sidewalls 13 and 15 have slit valves, 59 therein. A batch of substrates is transferred into the cooling chamber 44 through a slit valve, 59 (FIG. 19A) in sidewall 15. When all of the shelves are filled, the slit valve, 59 is closed and the chamber 44 is brought to vacuum by means of a conventional evacuation pump (not shown). When the desired pressure is reached, a slit valve 11 in the sidewall 13 adjacent to the robot chamber 50 opens to allow the robot to transfer the substrates 32 one at a time to the heating chamber 42. For maximum efficiency of the vacuum system 40, two cooling/load lock chambers 44 are provided so that when one batch of glass substrates 32 are being processed, a second batch of glass substrates 32 is being loaded into the system 40 at atmospheric pressure and brought to vacuum in chamber 44.

Referring again to FIGS. 16A-18A, the heating and cooling cassettes are mounted on an elevator 60. The elevator can move the cassettes 43 and 45 up and down so that a different conductive shelf 28 is presented to the robot after each transfer of a glass substrate 32. These elevator mechanisms are conventional and do not need to be described in detail herein. The elevator mechanism itself can be outside of the system 40 and connected via a seal through a lower wall of the system 40. Thus the cassettes 43, 45 move in the direction of the arrow 62 and the glass substrates 32 move in the direction of arrow 64 during transfer.

The glass substrates are first loaded into a load lock/cooling cassette where they can be brought under vacuum. The number of glass substrates that can be heated or cooled at once is not critical, and will be chosen depending upon a convenient size of the heating/cooling cassettes, and the relative amount of time required to heat, transfer and process the glass substrates. Then the glass substrates are transported one by one to the heating cassette where they are radiantly heated to processing temperatures, e.g., about 350°-400° C. After the load lock is emptied, a valve can be closed to vent it to atmosphere, when it is reloaded and pumped down again to vacuum.

The glass substrates are then transferred one-at-a-time to one or more film processing chambers for deposition of one or more thin films thereon. After all depositions are complete, the glass substrate is transferred back to the cooling cassette and a new glass substrate is placed back in the heating cassette. After the last glass substrate is exchanged in the cooling chamber cassette, a slit valve in the vacuum side is closed and the load lock/cooling chamber can be vented to atmosphere. During this time the glass substrates are cooled to about room temperature.

In the alternative process, a batch of large area glass substrates is transferred into a cassette in a cooling/load lock chamber, where the plates are brought to vacuum, transferred to a heating chamber and heating cassette where they are brought to CVD or other processing temperatures, transferred singly to one or more single substrate processing chambers, transferred back to the cooling cassette in the load lock chamber wherein they are cooled to ambient temperatures and vented to ambient pressure. The substrates can then be transferred out of the vacuum system.

In one processing embodiment, a substrate temperature may be maintained at about 400° C. or less, preferably between about 20° C. and about 400° C., more preferably between about 100° C. and about 300° C., such as about 130° C. For deposition of silicon films, a silicon-based gas and a hydrogen-based gas are provided. Suitable silicon based gases include, but are not limited to silane (SiH₄), disilane (Si₂H₆), silicon tetrafluoride (SiF₄), silicon tetrachloride (SiCl₄), dichlorosilane (SiH₂Cl₂), and combinations thereof. Suitable hydrogen-based gases include, but are not limited to hydrogen gas (H₂). The p-type dopants of the p-type silicon layers may each comprise a group III element, such as boron or aluminum. Preferably, boron is used as the p-type dopant. Examples of boron-containing sources include trimethylboron (TMB (or B(CH₃)₃)), diborane (B₂H₆), BF₃, B(C₂H₅)₃, and similar compounds. Preferably, TMB is used as the p-type dopant. The n-type dopants of the n-type silicon layer may each comprise a group V element, such as phosphorus, arsenic, or antimony. Preferably, phosphorus is used as the n-type dopant. Examples of phosphorus-containing sources include phosphine and similar compounds. The dopants are typically provided with a carrier gas, such as hydrogen, argon, helium, and other suitable compounds. In the process regimes disclosed herein, a total flow rate of hydrogen gas is provided. Therefore, if a hydrogen gas is provided as the carrier gas, such as for the dopant, the carrier gas flow rate should be subtracted from the total flow rate of hydrogen to determine how much additional hydrogen gas should be provided to the chamber.

Exemplary process recipes that may be used in apparatus described herein are described below. In these embodiments, source powers in the present disclosure are expressed as Watts supplied to an electrode per substrate area. For example, for a source power of 10,385 Watts supplied to an electrode to process a substrate having dimensions of 220 cm×260 cm, the source power would be 10,385 W/(220 cm×260 cm)=180 mW/cm². For the embodiments below, source power is provided at a power density between about 1 W/cm² and about 6 W/cm², such as about 3 W/cm². In some depositions, power may be ramped up or down from a first value to a second value during the deposition. Chamber pressure is typically maintained between about 10 mTorr and about 1 Torr, such as between about 100 mTorr and about 200 mTorr.

Certain embodiments of depositing a p-type microcrystalline silicon contact layer, such as contact layer 330 of FIG. 3, may comprise providing a gas mixture of hydrogen gas to silane gas in ratio of about 10:1 or greater. In some embodiments, the gas ratio of hydrogen to silane is about 200:1 or greater. Silane gas may be provided at a flow rate between about 0.1 sccm/L and about 0.8 sccm/L. Hydrogen gas may be provided at a flow rate between about 60 sccm/L and about 500 sccm/L. Trimethylboron may be provided at a flow rate between about 0.0002 sccm/L and about 0.0016 sccm/L. In other words, if trimethylboron is provided in a 0.5% molar or volume concentration in a carrier gas, then the dopant/carrier gas mixture may be provided at a flow rate between about 0.04 sccm/L and about 0.32 sccm/L. The flow rates in the present disclosure are expressed as sccm per interior chamber volume. The interior chamber volume is defined as the volume of the interior of the chamber in which a gas can occupy.

The deposition rate of the p-type microcrystalline silicon contact layer may be about 10 Å/min or more. The p-type microcrystalline silicon contact layer has a crystalline fraction between about 20 percent and about 80 percent, preferably between 50 percent and about 70 percent.

Certain embodiments of depositing a p-type amorphous silicon layer, such as the silicon layer 110 of FIG. 1, FIG. 2, or FIG. 3, may comprise providing a gas mixture of hydrogen gas to silane gas in a ratio of about 20:1 or less. Silane gas may be provided at a flow rate between about 1 sccm/L and about 10 sccm/L. Hydrogen gas may be provided at a flow rate between about 5 sccm/L and 60 sccm/L. Trimethylboron may be provided at a flow rate between about 0.005 sccm/L and about 0.05 sccm/L. In other words, if trimethylboron is provided in a 0.5% molar or volume concentration in a carrier gas, then the dopant/carrier gas mixture may be provided at a flow rate between about 1 sccm/L and about 10 sccm/L. Methane may be provided at a flow rate between about 1 sccm/L and 15 sccm/L. The deposition rate of the p-type amorphous silicon layer may be about 100 Å/min or more. Methane or other carbon containing compounds, such C₃H₈, C₄H₁₀, C₂H₂, can be used to improve the window properties (e.g. to lower absorption of solar radiation) of p-type amorphous silicon layer. Thus, an increased amount of solar radiation may be absorbed through the intrinsic layers and thus cell efficiency is improved.

Certain embodiments of depositing an intrinsic type amorphous silicon layer, such as the silicon layer 112 of FIG. 1, FIG. 2, or FIG. 3, comprises providing a gas mixture of hydrogen gas to silane gas in a ratio of about 20:1 or less. Silane gas may be provided at a flow rate between about 0.5 sccm/L and about 7 sccm/L. Hydrogen gas may be provided at a flow rate between about 5 sccm/L and 60 sccm/L. The deposition rate of the intrinsic type amorphous silicon layer may be about 100 Å/min or more.

Certain embodiments of depositing an n-type amorphous silicon buffer layer, such as the silicon layer 228 of FIG. 2, comprise providing hydrogen gas to silicon gas in a ratio of about 20:1 or less. Silane gas may be provided at a flow rate between about 1 sccm/L and about 10 sccm/L. Hydrogen gas may be provided at a flow rate between about 4 sccm/L and about 50 sccm/L. Phosphine may be provided at a flow rate between about 0.0005 sccm/L and about 0.0075 sccm/L. In other words, if phosphine is provided in a 0.5% molar or volume concentration in a carrier gas, then the dopant/carrier gas mixture may be provided at a flow rate between about 0.1 sccm/L and about 1.5 sccm/L. The deposition rate of the n-type amorphous silicon buffer layer may be about 200 Å/min or more.

Certain embodiments of depositing a n-type microcrystalline silicon layer, such as the silicon layer 114 of FIG. 1, FIG. 2, or FIG. 3, may comprise providing a gas mixture of hydrogen gas to silane gas in a ratio of about 100:1 or more. Silane gas may be provided at a flow rate between about 0.1 sccm/L and about 0.8 sccm/L. Hydrogen gas may be provided at a flow rate between about 30 sccm/L and about 250 sccm/L. Phosphine may be provided at a flow rate between about 0.0005 sccm/L and about 0.004 sccm/L. In other words, if phosphine is provided in a 0.5% molar or volume concentration in a carrier gas, then the dopant/carrier gas may be provided at a flow rate between about 0.1 sccm/L and about 0.8 sccm/L. The deposition rate of the n-type microcrystalline silicon layer may be about 50 Å/min or more. The n-type microcrystalline silicon layer has a crystalline fraction between about 20 percent and about 80 percent, preferably between 50 percent and about 70 percent.

Certain embodiments of depositing a p-type microcrystalline silicon layer, such as silicon layer 118 of FIG. 1, FIG. 2, or FIG. 3, comprises providing a gas mixture of hydrogen gas to silane gas in a ratio of about 200:1 or greater. Silane gas may be provided at a flow rate between about 0.1 sccm/L and about 0.8 sccm/L. Hydrogen gas may be provided at a flow rate between about 60 sccm/L and about 500 sccm/L. Trimethylboron may be provided at a flow rate between about 0.0002 sccm/L and about 0.0016 sccm/L. In other words, if trimethylboron is provided in a 0.5% molar or volume concentration in a carrier gas, then the dopant/carrier gas mixture may be provided at a flow rate between about 0.04 sccm/L and about 0.32 sccm/L. The deposition rate of the p-type microcrystalline silicon layer may be about 10 Å/min or more. The p-type microcrystalline silicon contact layer has a crystalline fraction between about 20 percent and about 80 percent, preferably between 50 percent and about 70 percent.

Certain embodiments of depositing an intrinsic type microcrystalline silicon layer, such as silicon layer 120 of FIG. 1, FIG. 2, or FIG. 3, may comprise providing a gas mixture of silane gas to hydrogen gas in a ratio between 1:20 and 1:200. Silane gas may be provided at a flow rate between about 0.5 sccm/L and about 5 sccm/L. Hydrogen gas may be provided at a flow rate between about 40 sccm/L and about 400 sccm/L. In certain embodiments, the silane flow rate may be ramped up from a first flow rate to a second flow rate during deposition. In certain embodiments, the hydrogen flow rate may be ramped down from a first flow rate to a second flow rate during deposition. The deposition rate of the intrinsic type microcrystalline silicon layer may be about 200 Å/min or more, preferably 500 Å/min. The microcrystalline silicon intrinsic layer has a crystalline fraction between about 20 percent and about 80 percent, preferably between 55 percent and about 75 percent. A microcrystalline silicon intrinsic layer having a crystalline fraction of about 70% or below provided an increase in open circuit voltage and leads to higher cell efficiency.

Certain embodiments of a method depositing a n-type amorphous silicon layer, such as the silicon layer 122 of FIG. 1, FIG. 2, or FIG. 3, may comprise depositing an optional first n-type amorphous silicon layer at a first silane flow rate and depositing a second n-type amorphous silicon layer over the first optional n-type amorphous silicon layer at a second silane flow rate lower than the first silane flow rate. The first optional n-type amorphous silicon layer may comprise providing a gas mixture of hydrogen gas to silane gas in a ratio of about 20:1 or less. Silane gas may be provided at a flow rate between about 1 sccm/L and about 10 sccm/L. Hydrogen gas may be provided at a flow rate between about 4 sccm/L and about 40 sccm/L. Phosphine may be provided at a flow rate between about 0.0005 sccm/L and about 0.0075 sccm/L. In other words, if phosphine is provided in a 0.5% molar or volume concentration in a carrier gas, then the dopant/carrier gas mixture may be provided at a flow rate between about 0.1 sccm/L and about 1.5 sccm/L. The deposition rate of the first n-type type amorphous silicon layer may be about 200 Å/min or more. The second n-type amorphous silicon layer may comprise providing a gas mixture of hydrogen gas to silane gas in a ratio of about 20:1 or less. Silane gas may be provided at a flow rate between about 0.1 sccm/L and about 1 sccm/L. Hydrogen gas may be provided at a flow rate between about 1 sccm/L and about 10 sccm/L. Phosphine may be provided at a flow rate between 0.01 sccm/L and about 0.075 sccm/L. In other words, if phosphine is provided in a 0.5% molar or volume concentration in a carrier gas, then the dopant/carrier gas mixture may be provided at a flow rate between about 2 sccm/L and about 15 sccm/L. The deposition rate of the second n-type type amorphous silicon layer may be about 100 Å/min or more. The second n-type amorphous silicon layer is heavily doped and has a resistivity of about 500 Ohm-cm or below. It is believed that the heavily n-type doped amorphous silicon provides improved ohmic contact with a TCO layer, such as layer TCO layer 124. Thus, cell efficiency is improved. The optional first n-type amorphous silicon is used to increase the deposition rate for the entire n-type amorphous silicon layer. It is understood that the n-type amorphous silicon layer may be formed without the optional first n-type amorphous silicon and may be formed primarily of the heavily doped second n-type amorphous layer.

A silicon nitride layer may be deposited using an antenna structure similar to those described herein. Using microwave power, as described above, at a chamber temperature of 130° C. and chamber pressure between about 100 mTorr and about 200 mTorr, a SiN layer may be deposited on a substrate at a deposition rate of about 4,200 Å/min.

A number of embodiments of the invention have been described. In particular, most embodiments described herein specify or suggest processing of substrates in a substantially vertical orientation. Processing of substrates in positions other than substantially vertical positions, for example horizontal or substantially horizontal positions, is also contemplated using the concepts embodied herein. Various other modifications may also be made without departing from the spirit and scope of the invention.

What is claimed is:

1. A system for vacuum processing of substrates, comprising:
a load-lock chamber; and
a plasma processing chamber coupled to the load-lock chamber and having a single processing volume, the processing volume separated into two processing regions by one or more substantially vertical antennas, each processing region configured to accept a substrate in a substantially vertical orientation.

2. The system of claim 1, wherein the load-lock chamber is configured to accept at least one vertically oriented substrate.

3. The system of claim 1, wherein the load-lock chamber is configured to accept at least one horizontally oriented substrate.

4. The system of claim 1, wherein the antennas protrude from the top of the plasma processing chamber.

5. The system of claim 1, wherein the antennas protrude from the top and bottom of the plasma processing chamber.

6. The system of claim 1, wherein the processing regions hold the substrates in a face-to-face orientation.

7. The system of claim 1, further comprising one or more gas sources extending vertically between the processing regions.

8. The system of claim 1, wherein the one or more antennas each comprise a deposition shield.

9. The system of claim 1 further comprising a frame disposed in the system, the frame operable to move the substrate vertically in the system.

10. The system of claim 9 further comprising a loader disposed between the load-lock chamber and the processing chamber, the loader operable to load substrates vertically onto the frame.

11. The system of claim 9, wherein the frame comprises a plurality of fingers to hold the substrate vertically on the frame.

12. The system of claim 1 further comprising a conveyor operable to move the substrate into the processing chamber.

13. The system of claim 1 further comprising at least two conveyors operable to move two substrates into the processing chamber in a face to face relation.

14. A system for vacuum processing of substrates, comprising:
a load-lock chamber configured to stage substrates in a horizontal position;
a PECVD chamber having a single processing region and at least two substantially vertical substrate processing regions separated by a vertically oriented antenna structure centrally located in the processing region; and
a loader for moving substrates between the load-lock chamber and the PECVD chamber.

15. The system of claim 14, wherein the antenna structure is coupled to a microwave frequency power source.

16. The system of claim 14, further comprising at least two conveyors operable to move two substrates into the PECVD chamber in a face to face relation.

17. The system of claim 14, further comprising a transfer chamber disposed between the load-lock chamber and the PECVD chamber.

18. The system of claim 16, further comprising a plurality of PECVD chambers oriented for vertical processing of substrates coupled to the transfer chamber.

19. A method of PECVD processing a substrate, the method comprising:
transferring two substrates from a load-lock chamber to a PECVD chamber, the substrates having a vertical face to face orientation in the PECVD chamber;
forming a single plasma field between the two substrates;
performing a PECVD process on the two substrates simultaneously using the single plasma field; and
returning the substrates to the load-lock chamber.

20. The method of claim 19, wherein forming the single plasma field between the two substrates comprises coupling microwave frequency power to a vertically orientated linear antenna.
